(19) United States
(12) Patent Application Publication
(10) Pub. No.: US 2022/0061236 A1
(43) Pub. Date: Mar. 3, 2022

(54) ACCESSING AGRICULTURE PRODUCTIVITY AND SUSTAINABILITY

(71) Applicant: THE BOARD OF TRUSTEES OF THE UNIVERSITY OF ILLINOIS, Urbana, IL (US)

(72) Inventors: Kaiyu Guan, Champaign, IL (US); Bin Peng, Urbana, IL (US); Chongya Jiang, Urbana, IL (US); Wang Zhou, Urbana, IL (US); Jingwen Zhang, Urbana, IL (US); Yizhi Huang, Champaign, IL (US); Jian Peng, Champaign, IL (US); Sibo Wang, Champaign, IL (US)

(21) Appl. No.: 17/445,928

(22) Filed: Aug. 25, 2021

Related U.S. Application Data
(60) Provisional application No. 63/070,250, filed on Aug. 25, 2020.

(51) Int. Cl. A01G 25/16; A01B 79/00; G06N 20/00

(52) U.S. Cl. CPC A01G 25/16; G06N 20/00; A01B 79/005

(57) ABSTRACT

An integrated multi-scale modeling platform is utilized to assess agricultural productivity and sustainability. The model is used to assess the environmental impacts of agricultural management from individual fields to watershed/basin to continental scales. In addition, an integrated irrigation system is developed using data and a machine-learning model that includes weather forecast and soil moisture simulation to determine an irrigation amount for farmers. Next, crop cover classification prediction can be established for an ongoing growing system using a machine learning or statistical model to predict the planted crop type in an area. Finally, a method of predicting key phenology dates of crops for individual field parcels, farms, or parts of a field parcel, in a growing season, can be established.

### CROSS-REFERENCE TO RELATED APPLICATIONS

This application claims priority under 35 U.S.C. § 119 to provisional patent application U.S. Ser. No. 63/070,250, filed Aug. 25, 2020. The provisional patent application is herein incorporated by reference in its entirety, including without limitation, the specification, claims, and abstract, as well as any figures, tables, appendices, or drawings thereof.

### STATEMENT AS TO FEDERALLY SPONSORED RESEARCH

This invention was made with government support under 1847334 awarded by the National Science Foundation, under 2019-67021-29312 awarded by the United States Department of Agriculture/National Institute of Food and Agriculture and under DE-SC0018420 awarded by the Department of Energy. The government has certain rights in the invention.

### FIELD OF THE INVENTION

Aspects and/or embodiments of the disclosure are directed towards systems and/or methods for an integrated multi-scale modeling platform to assess agricultural productivity and sustainability (IMAPS), a scalable and cost-effective precision irrigation scheme with field-scale ET products based on supply-demand dynamics, a method of generating and refining crop types classification and acreage forecast during the crop growing season, and a method to predict crop sowing/planting date from time series remote sensing images and weather/environmental information.

### BACKGROUND OF THE INVENTION

Human beings are facing great challenges in maintaining food security and environmental quality under climate change and land use intensification. Agricultural management is a critical factor determining crop production and its environmental footprint. Though the concept of “best management practices” has long been proposed to minimize the environmental impacts of agricultural management, there is still a huge gap towards prescribing best management practices locally at the field scale which minimally contribute to the total environmental burden at the watershed scale. In addition, conservation management practices have been recommended to improve soil health, and possibly to enhance carbon sequestration over cropland which may help mitigate climate change. However, no consensus has been achieved on whether the net greenhouse gas emissions could be reduced by adopting conservation management practices and how large their climate change mitigation potential could be, if there is any. Some entities in the private sector and non-governmental organizations have recently been trying to use the carbon market to generate incentives for farmers to adopt conservation management practices. However, there are still great challenges in accounting and verifying the carbon credit in an accurate and scalable manner. Moreover, the impacts of different management practices on carbon and water (blue/green/grey) footprints of agricultural production are separately treated in existing studies. Therefore, an accurate and scalable solution to assess the environmental impacts (including both carbon and water) of different management practices from field to watershed scales is highly desired in both academia and industry.

Systems modeling is a valuable tool to explore different potential solutions for the food-energy-water-nutrient nexus over agricultural landscape. However, either current land surface models, hydrological models, or crop models are not ideal tools for this exercise. Land surface models solve energy, water, carbon, and nutrient balances. However, they generally have over-simplified representations of surface heterogeneity using land-cover type based tiling approach, and the impacts from soil heterogeneity and topography are largely neglected in these kind of models as they are mainly developed for large-scale land-atmosphere interaction applications. Hydrological models have their strengths in representing hydrologic processes and connectivity. However, the current hydrological models seldomly simulate energy balance, carbon and nutrient cycles, as well as crop growth and management practices at the field scale. Crop models can simulate crop growth and productivity under different management practices at the field scale. However, the landscape impact of crop cultivation can hardly be assessed using agronomy-based crop models due to their lack of representation for either hydrological or biochemical processes and landscape heterogeneity. Therefore, there is an urgent need to develop an integrated modeling framework that can simulate both field-scale processes and their large-scale environmental impacts. To facilitate assessing carbon and water footprints of agricultural cultivation at the same time, the integrated modeling framework should be able to simulate coupled energy-water-carbon-nutrient cycles from field to watershed scales.

Representing heterogeneity over the agricultural landscape is one of the most critical issues when designing an integrated modeling framework. Traditional hydrological models use sub-basin, watersheds, or hydrologic response units as their finest spatial elements, while most of the land surface models use grids and sub-grid tiling to represent the surface heterogeneity. For the agricultural landscape, a discretization of the land surface is the field boundary, which is largely overlooked in traditional hydrological and land surface modeling efforts. Every field is unique in terms of their soil and drainage condition, and most importantly the management activities of individual farmers which largely determine that each field is relatively homogeneous with the same management pattern (i.e., same cropping system, sowing/harvesting scheduling, fertilization and tillage practices). Representing individual fields in the model could help inform farmers, the most important stakeholders of their own contribution to sustainability at the landscape scale. Moreover, a modeling tool that operates at field scale could also help farmers for their precision farming when the sub-field heterogeneity is considered by using some agronomically reasonable and efficient approaches, such as identifying management zones within each field.

Besides field boundary, drainage ditches constitute man-made hydrological discontinuities in farmed catchments, which is another missing piece in existing models. On one hand, these quasi-linear elements are expected to influence hydrological response during flood events as they do not necessarily follow the topographical gradient. Study has indicated that hydrographs simulated using channel networks automatically extracted from DEM cannot match with the observed hydrograph in both phase and magnitude at artificially drained agricultural land. On the other hand, the agricultural landscape is the largest contributor for riparian nitrates and phosphates and drainage ditches also mediate the flow of pollutants from agroecosystems to downstream water bodies. One can expect that the type and level of chemical processes (such as denitrification) would be very different in water traveling in the ditch network and surface/subsurface flow. However, the current modeling studies seldom consider the biochemical effects of drainage ditches. Though some ditch-related conservation practices (such as two-stage ditch and vegetation ditch) have been proposed for nutrient removal, the regional impact of adopting those practices can only be evaluated when the ditch-related processes are represented in the model.

Models are prone to uncertainties from model structure, parameters and input data. Uncertainties from model structure are intrinsic and mainly depend on how the physical world is represented in the model (i.e., which process is represented, which process is not represented, and how is the relationship between different processes represented). Model parameters result from parameterization, which is frequently used in land surface models, hydrological models, and crop models to represent those unobserved processes. There are two groups of parameters in process-based models. The first is process-specific, which does not vary over space and time (e.g., the maximum microbial denitrification rate), and can therefore be obtained through calibration and validation at local scale. The second is location-specific, which is now largely unconstrained in process-based models. Spatially-explicit calibration could be a promising way to constrain these location-specific parameters given more and more geospatial observations become available. Imperfect input data could also lead to uncertainties in model simulations, such as weather forcing, soil characteristics and initial condition. Observation provides direct constraints to model simulations. Traditionally, models are developed and validated at local scale with limited experimental data as constraints. With the advancement of new data collection technologies, such as remote sensing, wireless sensor network (WSN), and internet of things (IoT), more and more observation data become available at regional to global scales. Using observation data to constrain process-based models, i.e., data-model fusion, provides a promising way forward to improve model prediction performance.

Finally, thus far there is no model that can integrate the life-cycle analysis (LCA) to the farm-level information. Farm-level information remains as the largest uncertainty in the life-cycle analysis for agriculture and biofuel production.

Therefore, there is a need in the art to provide the historical and real-time field-level information to enable life cycle analysis from an individual field to any aggregated regional scales, and also allow scenario assessments of adopting different management practices and crops for the agricultural and food production. This innovation can generate new insights on assessing and optimizing the supply chain efficiency for the agricultural/food industry and bioeconomy industry.

### SUMMARY OF THE INVENTION

The following objects, features, advantages, aspects, and/or embodiments, are not exhaustive and do not limit the overall disclosure. No single embodiment need provide each and every object, feature, or advantage. Any of the objects, features, advantages, aspects, and/or embodiments disclosed herein can be integrated with one another, either in full or in part.

It is a primary object, feature, and/or advantage of the invention to improve on or overcome the deficiencies in the art.

According to some aspects, the present disclosure develops an Integrated Multi-scale modeling platform to assess Agricultural Productivity and Sustainability, named “IMAPS”. The IMAPS modeling framework is designed to assess the environmental impacts of agricultural management from individual fields to watershed/basin to continental scales. A scalable and hierarchical discretization (SHD) scheme for surface heterogeneity representation over agricultural landscape is designed for the IMAPS, in which each cropland parcel can be individually represented enabling hyper-resolution simulation. The SFID scheme is then coupled with an advanced agroecosystem model to simulate coupled energy-water-carbon-nutrient cycling processes at sub-field to field scales. Lateral water and nutrient fluxes are either dynamically routed along a ditch-river network derived from high-resolution remote sensing products to the watershed outlets (FIG. 2) or directly routed to the watershed outlets using a data-driven scaling approach. Multi-source observation data, including those from satellite/airborne/proximal remote sensing, wireless sensor network (WSN), Internet of Things (IoT), Eddy-Covariance (EC) flux towers, ground surveys, in-situ field experiments, standard streamflow gauges, and governmental statistical data are integrated within the IMAPS system to constrain the process-based model through a generic model-data fusion framework (FIG. 3). In particular, ubiquitous satellite-derived measurements will be used to constrain model simulation for each field parcel, which will enable the location-specific simulation to achieve high accuracy. Both greenhouse gas (GHG) emissions (carbon footprint) and water quantity/quality (water footprint) are explicitly simulated in the MAPS modeling framework, making it an ideal platform to assess the sustainability and guide the BMP design from field to watershed/basin to continental scales. Scenario and life cycle analysis is used in the IMAPS system to assess changes of both crop productivity and environmental footprint under different agricultural management practices and climate change. A comprehensive computer database is developed to store and archive all the input and output data of the IMAPS modeling platform and a visualization website portal is developed to efficiently communicate the simulation results with users.

Additional aspects and/or embodiments are provided that include an integrated irrigation system, combining one or more of the following approaches: (1) use of satellite-based BESS-STAIR ET data or CropEyes sensor derived ET data to constrain a hydrological model; (2) once the hydrological model is constrained, both water supply (i.e., soil moisture) and water demand (i.e. vapor pressure deficit) are considered to jointly determine when crop is under water stress and requires irrigation; (3) inclusion of weather forecast for the ET calculation and soil moisture simulation; and (4) if farmers do not provide their irrigation information, use of a model-data fusion method to estimate irrigation timing and amount and thus can continue to provide farmer irrigation information without requesting their data.

In certain embodiments, the technology (the dynamic precision irrigation scheme) aims to provide precision irrigation scheduling based on plant water stress considering soil moisture and VPD with the operational field-scale ET products and soil moisture from highly constrained hydrologic models. This precision irrigation scheme is water-efficient and can be applied to every individual field in large regions, such as county, state, or nation.

There are some existing efforts attempted to provide precision irrigation scheduling based on some indexes interpreting plant water stress, such as: maximum allowable depletion (MAD), crop water stress index (CWSI). These processes determine plant water stress focusing on limited aspects and require accurate field-scale observations of soil moisture and/or canopy temperature (satellite observations involving large uncertainty), thus unscalable. In certain embodiments, the process and system (new precision irrigation scheme) use new concepts (supply-demand dynamics among the soil-plant-atmosphere continuum, SPAC) to define plant water stress considering soil moisture and VPD for precision irrigation based on the operational field-scale ET products with high-accuracy.

Certain embodiments include systems and methods (new precision irrigation scheme) that provide operational field-scale ET products with a high spatiotemporal resolution and define plant water stress considering soil moisture and VPD for precision irrigation. With the operational ET products and new definition of plant water stress for precision irrigation, the precision irrigation process is water-efficient and can be applied at every individual field in large regions, such as county, state, or nation.

Still further aspects and/or embodiments relate to effective real-time crop cover classification prediction is essential to real-time large-scale crop monitoring. Embodiments of the present disclosure include a system and method that employs a deep-learning-based method to accurately classify crop cover types during the growing season, and continuously refining the classification. In certain embodiments, the method includes three components: a prior-knowledge model, an evolving remote-sensing-based model, and an evolving weight model. Historical planting information is incorporated into the prior-knowledge model to improve the performance, especially in the pre and early season when remote sensing images do not contain distinguishable crop signals. Remote sensing data available on the day of prediction is used by the remote-sensing-based model to extract spatial and temporal information that can be used to classify the crops. The two models are then combined using the weight model, which evolves over time and allows the remote-sensing-based model to be increasingly dominant as more information is available. An effective national acreage model is also developed to aggregate this method's prediction to regional and corn and soybean acreage.

Certain embodiments aim to generate crop type classification that will be continuously refined as the growing season progresses at low cost but with high efficiency. Particularly, the technology overcomes the common failure of existing crop classification methods that the classification performances are unsatisfiable in the early stage of growing seasons. The technology provides an upstream dataset for various modeling applications such as in-season yield forecast, total crop production estimation, and prevented planting detection. It also provides reliable regional and national planted acreage estimation that is essential to global food monitoring and security.

Certain embodiments include an algorithm/method that integrates historical planting information and remote sensing information together, using an evolving weight model to conduct the classification. Prior algorithms generate unsatisfiable predictions that cannot be used for further analysis at the beginning of the growing season, while embodiments of the present disclosure can obtain an accuracy of 85% in many regions showing in the validation results.

Certain embodiments include an innovative and highly effective method for crop cover classification in the real-time that incorporates both historical planting patterns and remote sensing images using an evolving weight model. In certain embodiments, the algorithm/method has been scaled up for national-scale crop cover classification at low cost but high efficiency, which is critical to field-level precision agriculture, early warning of food insecurity, and economic market. Certain embodiments include an effective national acreage model to predict corn and soybean planting size on the national-scale, which play important roles in determining market price of corn and soybean.

Yet additional embodiments and/or aspects are provided that include systems and methods that estimate row crop sowing/planting date using time series of satellite remote sensing data without requesting any information from farmers. Certain embodiments consider both satellite and weather/environmental information together to estimate crop sowing/planting date. Certain embodiments include a method that estimates sowing/planting date at each individual field scale and is scalable for large area applications. Demonstration study has been conducted to estimate sowing/planting date for corn and soybean over the U.S. Midwest, and the results show that the method has the highest performance compared with other approaches.

Certain embodiments of the present disclosure estimate crop sowing/planting date without requesting any information from farmers.

Certain embodiments consider both satellite and weather/environmental information together to estimate crop sowing/planting date.

Certain embodiments allow one to know every crop field's sowing/planting date without asking farmers information.

Accordingly, the following methods, embodiments, and/or aspects of the disclosure may be included.

A method of predicting key phenology dates of crops for individual field parcels, farms, or parts of a field parcel, in a growing season comprising the following steps: a. Gathering environmental variables and remotely sensed data in the target growing season. b. Designing a statistical or machine learning model or explicit algorithms with parameters that predicts the phenology dates from the environmental variables or remotely sensed data. c. Optimize parameters in the model or algorithm using observation of key phenology dates and the corresponding environmental or remotely sensed data.

The method may also include wherein the statistical or machine learning model or explicit algorithm include the following steps: a. Generating an initial prediction using either environmental variables alone or remotely sensed data alone. b. Generating a refined prediction by predicting the errors of the initial prediction using inputs (remotely sensed or environmental) that have not been used in the first step.

The method may also include wherein growing season is {the current ongoing growing season, a past growing season} (maybe expand into separate dependent claims).

The method may also include wherein the explicit algorithm involves calculating thresholds based on descriptors of the geometric shape of time series of remotely sensed or environmental data.

The method may also include wherein the observation of phenology dates comes from survey or otherwise collected ground truth data.

The method may also include wherein the observation of phenology dates comes from predictions of another statistical or machine learning model.

The method may also include wherein the environmental variables include one or more such as: temperature, humidity, precipitation, and/or vapor pressure deficit.

The method may also include wherein the remotely sensed data can be satellite data, satellite-derived indices, airborne remote sensing data, UAV-collected data, data collected by ground vehicles, and/or synthetic data generated from any combination of the aforementioned sources.

These and/or other objects, features, advantages, aspects, and/or embodiments will become apparent to those skilled in the art after reviewing the following brief and detailed descriptions of the drawings. Furthermore, the present disclosure encompasses aspects and/or embodiments not expressly disclosed but which can be understood from a reading of the present disclosure, including at least: (a) combinations of disclosed aspects and/or embodiments and/or (b) reasonable modifications not shown or described.

### BRIEF DESCRIPTION OF THE DRAWINGS

The present patent application contains at least one drawing/photograph executed in color. Copies of this patent with color drawing(s)/photograph(s) will be provided to the Office upon request and payment of the necessary fee.

Several embodiments in which the invention can be practiced are illustrated and described in detail, wherein like reference characters represent like components throughout the several views. The drawings are presented for exemplary purposes and may not be to scale unless otherwise indicated.

FIG. 1 is a conceptual illustration of a field-to-watershed modeling system in accordance with one or more embodiments of the present disclosure.

FIG. 2 shows a pipeline for ditch extraction using multi-source and high-resolution remote sensing data in accordance with one or more embodiments of the present disclosure.

FIG. 3 shows a model-data fusion framework to constrain model uncertainty in accordance with one or more embodiments of the present disclosure.

FIG. 4 shows a map showing the geo-location and land cover types of Spoon River watershed as a demonstration.

FIG. 5 shows a ditch network over the Spoon River watershed. Blue lines represent the ditch network draining to the watershed outlet, while green lines represent ditch network draining out of the watershed outlet. Red lines represent field boundaries.

FIG. 6 shows changes of soil organic carbon (SOC) and nitrous dioxide emission (N2O) under different management practices over the Spoon River watershed.

FIG. 7 shows a demo dashboard for the visualization portal to communicate sustainability assessment results with users in accordance with one or more embodiments of the present disclosure.

FIG. 8 is a conceptual scheme of possible aspects to define plant water stress (soil moisture, water potential, and stomatal conductance) in accordance with embodiments of the present disclosure.

FIG. 9 shows a framework of a scalable and cost-effective precision irrigation scheme in accordance with an embodiment of the present disclosure.

FIG. 10 shows BESS-STAIR performance in accordance with an embodiment of the present disclosure. Left: a daily ET map in eastern Nebraska. Right: time series comparison of ET, potential evapotranspiration (PET) and ET/PET between BESS-STAIR daily estimations and flux tower observations in 2012.

FIG. 11 shows simulated soil moisture and VPD's co-regulation effect on stomatal conductance of maize based on Ecosys model simulations at GD site (40.93° N; 97.46° W) in Nebraska.

FIGS. 12A-D shows the new plant-centric plant water stress index based on the supply-demand dynamics (SDD) from the aspect of stomatal conductance in accordance with one or more embodiments of the present disclosure.

FIG. 13 shows relative difference and difference of irrigation amount, yield, profit, and irrigation water productivity between SDD (optimal universal function) and traditional MAD (50%) methods across 12 sites during the period from 2001 to 2019 in Nebraska.

FIG. 14 illustrates the framework of the model-data fusion approach for high spatial-temporal resolution irrigation estimation. Concurrent (CON): determine irrigation timing and amount concurrently. Sequential (SEQ): determine irrigation timing and amount sequentially.

FIGS. 15A-F are a collection of box plots of the statistical indexes (R, RMSE, and Bias) of irrigation estimation using CON and SEQ with different temporal scales (daily, weekly, and monthly) for all site-years in (a-c) eastern and (d-f) western Nebraska. The statistical indexes were calculated for each site-year. There were 24 and 52 site-years in the eastern and western Nebraska, respectively.

FIGS. 16A-B show scatter plots of (a) monthly and (b) annual irrigation estimations and irrigation records from CON and SEQ across 76 site-years in Nebraska. Black dashed lines indicated the 1-to-1 relationship. The red and blue lines were the regression lines of two methods (red: CON and blue: SEQ) with the 95% confidence interval. The probability density functions in the top and right sides denoted the kernel density estimations of irrigation records and irrigation estimations.

FIGS. 17A-B show time series of irrigation estimation using CON at (a) field (1013503) and (b) field (1013922) in the western Nebraska in 2015, planted with maize and soybean, respectively. The overlapped irrigation (red bar) denoted that the irrigation estimations (black bar with hatches) match the irrigation records (blue bar). The grey area denoted the 95% confidence interval of irrigation estimations from ten replicates.

FIG. 18 shows a map showing the U.S. Corn Belt states.

FIG. 19 shows a schematic overview of the fusion method of STAIR.

FIG. 20 shows the BlueBird Neural Network architecture for real-time classification of crop cover types.

FIG. 21 shows an example of corn-soybean rotation planting observed from the CDL data.

FIG. 22 shows the process of Long Short-Term Memory (LSTM) in accordance with an embodiment of the present disclosure. Xt stands for input at time t; ht stands for output at time t; Ct is the lstm cell at time t.

FIG. 23 shows a simple dense layer network with input dimension of 3, two hidden layers with dimension of 4, and output dimension of 2 in accordance with one or more embodiments of the present disclosure.

FIG. 24 shows distinguishing signals in satellite optical data for crop classification in accordance with one or more embodiments of the present disclosure.

FIG. 25 shows real time prediction using satellite optical data in accordance with an embodiment of the present disclosure.

FIG. 26 shows a real time weight example of four major land cover types in Illinois.

FIG. 27 shows divisions of the corn belt for model training purposes.

FIG. 28 shows corn and soybean real-time F1 score, Champaign, Ill.

FIG. 29 shows CDL comparison with BlueBird's pixel-level predictions on two different dates (June 1, August 30); In CDL and BlueBird's prediction, corn is marked as yellow and soybean is marked as green; In difference maps, black is correct pixel and orange is incorrect pixel.

FIGS. 30A-D show county-scale F1 score for corn and soybean on June 1 and August 30, wherein FIG. 26A shows the corn F1 scale for June 1 from 2014-19; FIG. 26B shows the corn F1 scale for August 30 from 2014-19; FIG. 26C shows the soybean F1 scale for June 1 from 2014-19; and FIG. 26D shows the soybean F1 scale for August 30 from 2014-19.

FIGS. 31A-D show density scatter map for county-scale acreage and NASS county level acreage for corn and soybean on June 1 and August 30, wherein FIG. 31A shows the density scatter map for corn on June 1 from 2014-19; FIG. 31B shows the density scatter map for corn on August 30 from 2014-19; FIG. 31C shows the density scatter map for soybeans on June 1 from 2014-19; and FIG. 31D shows the density scatter map for soybeans on August 30 from 2014-19.

FIG. 32 shows predicted national acreage vs NASS ground truth acreage on June 1 (left) and August 30 (right).

FIG. 33 shows the framework of a method to predict crop sowing/planting date in accordance with one or more embodiments of the present disclosure.

FIG. 34 shows a conceptual illustration of the WDRVI curve (gray) with the threshold date of the first and second rules (red), initial (green) and final (blue) sowing date estimations.

FIG. 35 is an example of the spatial maps of predicted and observed sowing dates for corn and soybean over 3 I-States (Iowa, Illinois, and Indiana), for selected years: 2000, 2002, 2004, 2006, 2008, 2010, and 2012. Panels from left to right show predictions for corn, ground truth for corn, predictions for soybean, and ground truth for soybean.

FIG. 36 is an overall scatter plot of predictions versus ground truth during 2000-2012. The left panel is for corn and the right panel is for soybean.

FIGS. 37A-B show yearly scatter plot of predictions versus ground truth during 2000-2012. FIG. 37A is for corn and FIG. 37B is for soybean.

An artisan of ordinary skill need not view, within isolated figure(s), the near infinite number of distinct permutations of features described in the following detailed description to facilitate an understanding of the invention.

### DETAILED DESCRIPTION OF THE INVENTION

The present disclosure is not to be limited to that described herein. Mechanical, electrical, chemical, procedural, and/or other changes can be made without departing from the spirit and scope of the invention. No features shown or described are essential to permit basic operation of the invention unless otherwise indicated.

Unless defined otherwise, all technical and scientific terms used above have the same meaning as commonly understood by one of ordinary skill in the art to which embodiments of the invention pertain.

The terms “a,” “an,” and “the” include both singular and plural referents.

The term “or” is synonymous with “and/or” and means any one member or combination of members of a particular list.

The terms “invention” or “present invention” are not intended to refer to any single embodiment of the particular invention but encompass all possible embodiments as described in the specification and the claims.

The term “about” as used herein refers to slight variations in numerical quantities with respect to any quantifiable variable. Inadvertent error can occur, for example, through use of typical measuring techniques or equipment or from differences in the manufacture, source, or purity of components.

The term “substantially” refers to a great or significant extent. “Substantially” can thus refer to a plurality, majority, and/or a supermajority of said quantifiable variable, given proper context.

The term “generally” encompasses both “about” and “substantially.”

The term “configured” describes structure capable of performing a task or adopting a particular configuration. The term “configured” can be used interchangeably with other similar phrases, such as constructed, arranged, adapted, manufactured, and the like.

Terms characterizing sequential order, a position, and/or an orientation are not limiting and are only referenced according to the views presented.

The “scope” of the invention is defined by the appended claims, along with the full scope of equivalents to which such claims are entitled. The scope of the invention is further qualified as including any possible modification to any of the aspects and/or embodiments disclosed herein which would result in other embodiments, combinations, subcombinations, or the like that would be obvious to those skilled in the art.

Aspects and/or embodiments including one or more aspects which embody the invention disclosed herein will be broken down into sections, which may be referred to as examples of the various aspects and/or embodiments. As will be understood, portions of any of the aspects, embodiments, and/or examples as provided herein can be swapped out and/or utilized with one another, even if not explicitly shown and/or described, and which will still be covered by the invention herein.

Therefore, a first section, which may be referred to as Section 1 discloses and describes aspects and/or embodiments that include an integrated multi-scale modeling platform to assess agricultural productivity and sustainability, (hereinafter, “IMAPS”). The IMAPS modeling framework is designed to assess the environmental impacts of agricultural management from individual fields to watershed/basin to continental scales. A scalable and hierarchical discretization (SHD) scheme for surface heterogeneity representation over agricultural landscape is designed for the IMAPS, in which each cropland parcel can be individually represented enabling hyper-resolution simulation. The SHD scheme is then coupled with an advanced agroecosystem model to simulate coupled energy-water-carbon-nutrient cycling processes at sub-field to field scales. Lateral water and nutrient fluxes are then dynamically routed along a ditch-river network derived from high-resolution remote sensing products. Multi-source observation data, including those from satellite/airborne/proximal remote sensing, wireless sensor network (WSN), Internet of Things (IoT), Eddy-Covariance (EC) flux towers, ground surveys, in-situ field experiments, standard streamflow gauges, and governmental statistical data are integrated within the IMAPS system to constrain the process-based model through a generic model-data fusion framework. Both greenhouse gas (GHG) emissions (carbon footprint) and water quantity/quality (water footprint) are explicitly simulated in the IMAPS modeling framework, making it an ideal platform to assess the sustainability and guide the BMP design from field to watershed/basin to continental scales. Scenario and life cycle analysis is used in the IMAPS system to assess changes of both crop productivity and environmental footprint under different agricultural management practices and climate change. A comprehensive computer database is developed to store and archive all the input and output data of the IMAPS modeling platform and a visualization website portal is developed to efficiently communicate the simulation results with users.

In certain embodiments, the IMAPS model is developed to fill the gaps in currently available modeling tools, which are not ideal ones for assessing agricultural productivity and sustainability at the same time and from field to watershed scales. The IMAPS modeling platform offers a valuable tool to explore potential solutions to food-energy-water nexus over the agricultural landscapes.

In certain embodiments, the IMAPS model is a modeling platform, which integrates (1) a new scalable and hierarchical discretization (SHD) scheme to represent surface heterogeneity, (2) a field-scale process-based model, (3) a dynamic ditch-river transport model, and (4) a generic model-data fusion framework. However, some parts of the model implementation could be from existing models, such as the field-scale process-based model.

Aspects of this technology include: (1) a new tiling system to represent the surface heterogeneity in hyper-resolution modeling over agricultural landscapes; (2) an automatic method of detecting ditch network; (3) a modeling system from field to watershed scales for both hydrology and biogeochemistry; (4) a data-driven scaling method to estimate one or more hydrological and water quality variables at a watershed outlet based on model-simulated hydrological and water quality variables over multiple granular cells within the watershed; (5) a model-data fusion framework for agricultural sustainability assessment by leveraging ubiquitous satellite data and other sensor data to enable high accuracy modeling at the field scale; (6) a modelling system for scenario and life cycle analysis in agricultural sustainability assessment; and (7) a visualization platform to communicate the results from agricultural sustainability assessment.

Next, in a second section referred to as Section/Example 2, aspects and/or embodiments are provided that include an integrated irrigation system, combining one or more of the following approaches:

(1) use of satellite-based BESS-STAIR ET data or CropEyes sensor derived ET data to constrain a hydrological model; (2) once the hydrological model is constrained, both water supply (i.e., soil moisture) and water demand (i.e. vapor pressure deficit) are considered to jointly determine when crop is under water stress and requires irrigation; (3) inclusion of weather forecast for the ET calculation and soil moisture simulation; and (4) if farmers do not provide their irrigation information, use of a model-data fusion method to estimate irrigation timing and amount and thus can continue to provide farmer irrigation information without requesting their data.

In certain embodiments, the technology (the dynamic precision irrigation scheme) aims to provide precision irrigation scheduling based on plant water stress considering soil moisture and VPD with the operational field-scale ET products and soil moisture from highly constrained hydrologic models. This precision irrigation scheme is water-efficient and can be applied to every individual field in large regions, such as county, state, or nation.

There are some existing efforts attempted to provide precision irrigation scheduling based on some indexes interpreting plant water stress, such as: maximum allowable depletion (MAD), crop water stress index (CWSI). These processes determine plant water stress focusing on limited aspects and require accurate field-scale observations of soil moisture and/or canopy temperature (satellite observations involving large uncertainty), thus unscalable. In certain embodiments, the process and system (new precision irrigation scheme) use new concepts (supply-demand dynamics among the soil-plant-atmosphere continuum, SPAC) to define plant water stress considering soil moisture and VPD for precision irrigation based on the operational field-scale ET products with high-accuracy.

Certain embodiments include systems and methods (new precision irrigation scheme) that provide operational field-scale ET products with a high spatiotemporal resolution and define plant water stress considering soil moisture and VPD for precision irrigation. With the operational ET products and new definition of plant water stress for precision irrigation, the precision irrigation process is water-efficient and can be applied at every individual field in large regions, such as county, state, or nation.

Next, in a third section referred to as Section/Example 3, aspects and/or embodiments relate to effective real-time crop cover classification prediction is essential to real-time large-scale crop monitoring. Embodiments of the present disclosure include a system and method that employs a deep-learning-based method to accurately classify crop cover types during the growing season, and continuously refining the classification. In certain embodiments, the method includes three components: a prior-knowledge model, an evolving remote-sensing-based model, and an evolving weight model. Historical planting information is incorporated into the prior-knowledge model to improve the performance, especially in the pre and early season when remote sensing images do not contain distinguishable crop signals. Remote sensing data available on the day of prediction is used by the remote-sensing-based model to extract spatial and temporal information that can be used to classify the crops. The two models are then combined using the weight model, which evolves over time and allows the remote-sensing-based model to be increasingly dominant as more information is available. An effective national acreage model is also developed to aggregate this method's prediction to regional and corn and soybean acreage.

Certain embodiments aim to generate crop type classification that will be continuously refined as the growing season progresses at low cost but with high efficiency. Particularly, the technology overcomes the common failure of existing crop classification methods that the classification performances are unsatisfiable in the early stage of growing seasons. The technology provides an upstream dataset for various modeling applications such as in-season yield forecast, total crop production estimation, and prevented planting detection. It also provides reliable regional and national planted acreage estimation that is essential to global food monitoring and security.

Certain embodiments include an algorithm/method that integrates historical planting information and remote sensing information together, using an evolving weight model to conduct the classification. Prior algorithms generate unsatisfiable predictions that cannot be used for further analysis at the beginning of the growing season, while embodiments of the present disclosure can obtain an accuracy of 85% in many regions showing in the validation results.

Certain embodiments include an innovative and highly effective method for crop cover classification in the real-time that incorporates both historical planting patterns and remote sensing images using an evolving weight model. In certain embodiments, the algorithm/method has been scaled up for national-scale crop cover classification at low cost but high efficiency, which is critical to field-level precision agriculture, early warning of food insecurity, and economic market. Certain embodiments include an effective national acreage model to predict corn and soybean planting size on the national-scale, which play important roles in determining market price of corn and soybean.

Finally, in the section referred to as Section/Example 4, embodiments and/or aspects are provided that include systems and methods that estimate row crop sowing/planting date using time series of satellite remote sensing data without requesting any information from farmers. Certain embodiments consider both satellite and weather/environmental information together to estimate crop sowing/planting date. Certain embodiments include a method that estimates sowing/planting date at each individual field scale and is scalable for large area applications. Demonstration study has been conducted to estimate sowing/planting date for corn and soybean over the U.S. Midwest, and the results show that the method has the highest performance compared with other approaches.

Certain embodiments of the present disclosure estimate crop sowing/planting date without requesting any information from farmers.

Certain embodiments consider both satellite and weather/environmental information together to estimate crop sowing/planting date.

Certain embodiments allow one to know every crop field's sowing/planting date without asking farmers information.

### Example 1: An Integrated Multi-Scale Modeling Platform to Assess Agricultural Productivity and Sustainability (IMAPS)

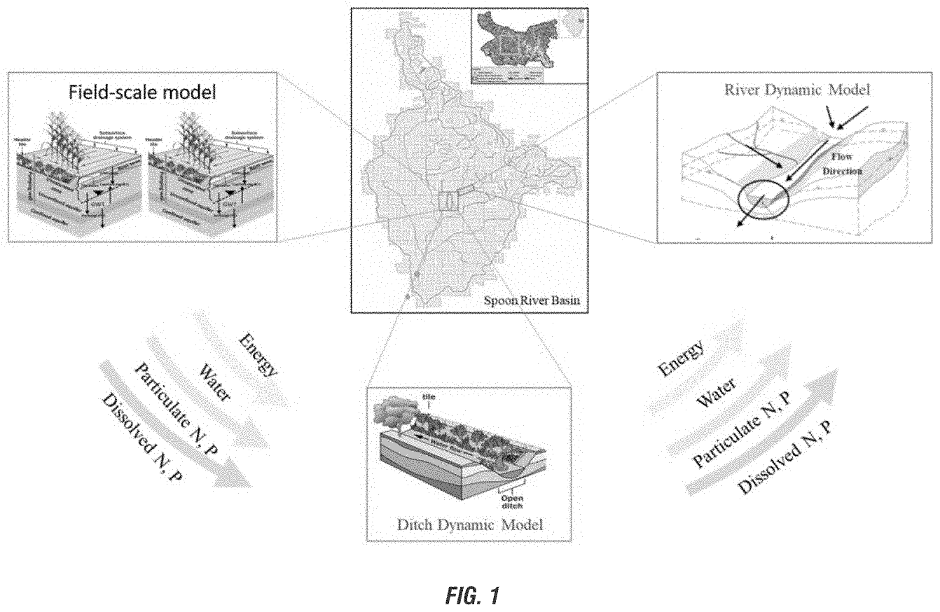

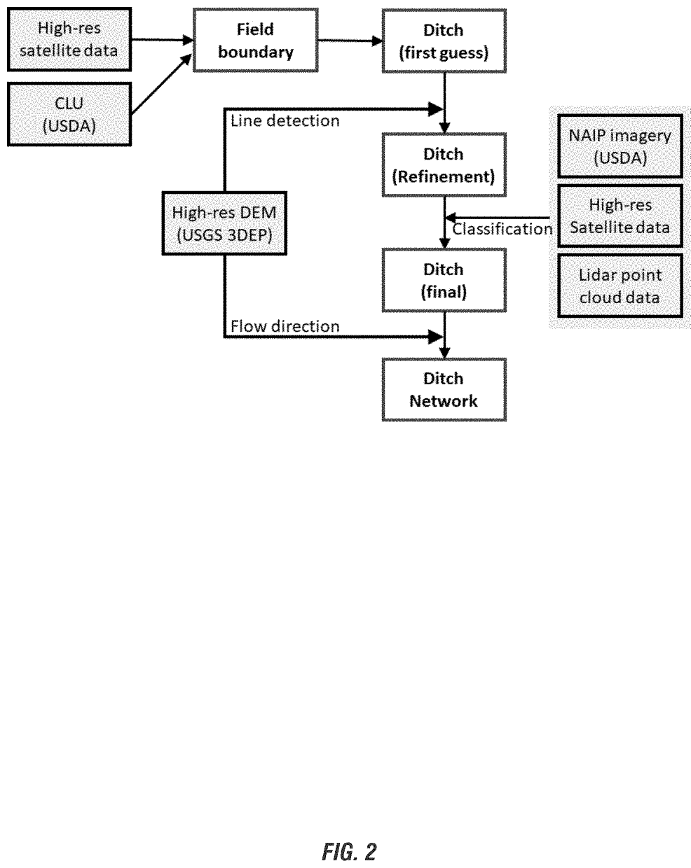

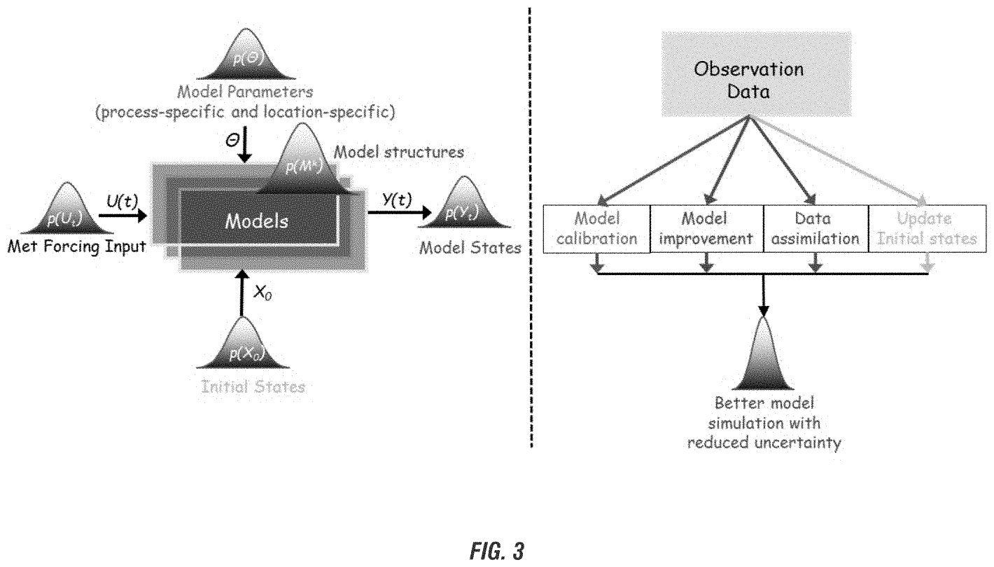

According to at least some aspects and/or embodiments provided herein, an Integrated Multi-scale modeling platform to assess Agricultural Productivity and Sustainability, named “IMAPS”, is developed and utilized. The IMAPS modeling framework is designed to assess the environmental impacts of agricultural management from individual fields to watershed/basin to continental scales (FIG. 1). A scalable and hierarchical discretization (SHD) scheme for surface heterogeneity representation over agricultural landscape is designed for the IMAPS, in which each cropland parcel can be individually represented enabling hyper-resolution simulation. The SHD scheme is then coupled with an advanced agroecosystem model to simulate coupled energy-water-carbon-nutrient cycling processes at sub-field to field scales. Lateral water and nutrient fluxes are either dynamically routed along a ditch-river network derived from high-resolution remote sensing products to the watershed outlets (FIG. 2) or directly routed to the watershed outlets using a data-driven scaling approach. Multi-source observation data, including those from satellite/airborne/proximal remote sensing, wireless sensor network (WSN), Internet of Things (IoT), Eddy-Covariance (EC) flux towers, ground surveys, in-situ field experiments, standard streamflow gauges, and governmental statistical data are integrated within the IMAPS system to constrain the process-based model through a generic model-data fusion framework (FIG. 3). In particular, ubiquitous satellite-derived measurements will be used to constrain model simulation for each field parcel, which will enable the location-specific simulation to achieve high accuracy. Both greenhouse gas (GHG) emissions (carbon footprint) and water quantity/quality (water footprint) are explicitly simulated in the IMAPS modeling framework, making it an ideal platform to assess the sustainability and guide the BMP design from field to watershed/basin to continental scales. Scenario and life cycle analysis is used in the IMAPS system to assess changes of both crop productivity and environmental footprint under different agricultural management practices and climate change. A comprehensive computer database is developed to store and archive all the input and output data of the IMAPS modeling platform and a visualization website portal is developed to efficiently communicate the simulation results with users.

1.1 New Tiling System

Embodiments of the present disclosure include a scalable and hierarchical discretization (SHD) scheme for surface heterogeneity representation over agricultural landscape:

The first level of discretization is to divide the globe or a specific region into hierarchical hydrologic units, such as basins, subbasins, and watersheds. The granularity of this discretization is flexible for different applications. For the United States, the USGS National Hydrography Dataset (NHD) contains a multi-level watershed boundary dataset, ranging from 2-digit to 12-digit hydrologic units.

The second level of discretization is to divide each hydrologic unit into cropland area and non-cropland area.

The third level of discretization is sub-area division: For the cropland area, the system treats individual fields (homogeneous cropping system and management practice in each growing season) as the basic landscape unit. The field boundaries can be either from administration survey data or from remote sensing delineations. Although the cropping system may change from year to year in a specific field due to crop rotation, the field boundary should be relatively stable. Here it is assumed that each field has a single crop type. The next step is to divide all the fields in the cropland area into a specific number (Ne) of elevation bands using the field-mean elevation by prescribing either Ne or elevation step (say per 50 m). This division ensures high-resolution pixels of a specific field are located in the same elevation band. For all the fields in a single elevation band, the step includes to further divide them into a specific number (NO of “typical fields”. Here the typical field number Nf can be determined by crop type and management practice combinations, for example, irrigated/rainfed corn field, and irrigated/rainfed soybean field. Nf can also be the total number of all fields in this elevation band, in which case each field is represented explicitly. For each individual field (either conceptually clustered or real field), the system divides all the within-field pixels into a specific number (Nm) of management zones clustered using high-resolution maps depicting soil characteristics, drainage condition, and yield potentials. These high-resolution maps can be obtained from existing data sources or remote sensing. Through the above divisions, all the fine scale (<=30 m) pixels in the cropland area are divided into Ne×Nf×Nm classes.

For the non-cropland area, the system and/or method follows a similar division strategy with the cropland area but based on individual pixels in high-resolution land cover maps. All the pixels in the unmanaged zone are firstly divided into a specific number (Ne) of elevation bands. The pixels in each elevation band are then divided into a specific number (Nv) of land cover types. Within each land cover type in each elevation band, a specific number (Ns) of soil groups are clustered using a high resolution (30 m) soil property map. Through the above divisions, all the fine scale (<=30 m) pixels in the non-cropland area are divided into Ne×Nv×Ns classes.

1.2 Method to Extract Drainage Ditch Network

Ditches are everywhere over agricultural landscapes to convey storm water and solute runoff from farm fields into river networks. The topology structure of ditch network and ditch characteristics (such as vegetated or non-vegetated) have significant impacts on water and solute runoff routing. However, these effects from the ditch network have been largely overlooked in previous hydrological simulations mainly due to lack of detailed information about the ditch network itself. This invention developed an automatic pipeline to extract drainage ditch networks over agricultural landscapes (FIG. 2). The pipeline contains two main steps: the first step is to find an initial guess of the location of ditches. Field boundaries are used as the first guess, which can be derived from high-resolution satellite imageries, such as Landsat and Sentinel-2 or directly taken from existing data sources, such as USDA Common Land Unit (CLU). The second step is to refine the initially guessed ditches. An automatic line extractor is used to detect line objects from very-high-resolution digital elevation model (DEM) data, such as the USGS 3DEP 1 m DEM data, within a buffer zone of the initially guessed ditches. The detected line objects are then classified into ditches and non-ditches using machine learning or deep learning with aerial images (such as USDA NAIP imagery), high-resolution satellite data (such as WorldView, GeoEye, IKONOS, QuickBird, SkySat, TripleSat, KOMPSAT, and Pleiades-1 etc), and/or Lidar point cloud data as input data. Flow direction along ditches were also determined through elevation data analysis. Finally, the topology of the ditch network is determined by tracing the flow direction along all the ditches.

1.3 Model Component

The model component of this invention includes a model that can simulate the biophysical and/or biogeochemical processes at each individual field and a model that can simulate water and/or nutrient transport processes in the ditch-river network. The former model can be a soil hydrology model, land surface model (such as Noah/Noah-MP, SWAP), crop model (DSSAT, APSIM) or ecosystem model (such as Daycent, DNDC, Agro-IBIS, Ecosys, CLM, ELM) that can be run in single-column mode or at point scale. Processes simulated by this model may vary depending on the application, and can include one or more of the following aspects:

(1) Soil water balance;

(2) Land surface energy balance;

(3) Crop growth;

(4) Canopy water balance;

(5) Canopy radiative transfer;

(6) Canopy energy balance;

(7) Canopy carbon uptake and biomass production;

(8) Soil carbon dynamics;

(9) Soil nutrient (one or more elements in nitrogen, phosphorus, and potassium) balance; or

(10) Field management practices (one or more in crop rotation, cover crops, tillage, irrigation, fertilization, pesticide).

The ditch-river transport model according to aspects and/or embodiments disclosed herein can either simulate water transport or simulate water, sediment, nutrient, and pollutant transport simultaneously. This ditch-river transport model can be either a dynamic model or a data-driven model. For the dynamic ditch-river transport model, a dynamic ditch model and a dynamic river model handle the water, sediment, nutrient, and pollutant dynamics in the ditch networks and river channels, respectively. Outputs (lateral water and nutrient fluxes) from the field-scale process-based model are directly used as the inputs to the ditch dynamic model. Both bare soil ditch and vegetated ditch can be simulated in the model by considering different model parameters (Manning's roughness coefficient and kinetic rates) related to roughness and nutrients residence time. Two methods to simulate water transport in the ditches, i.e., the Muskingum method and Hayami analytical approximation of the diffusive wave equation are incorporated and compared. The ditch network dataset derived using the proposed pipeline in aspects and/or embodiments disclosed herein is used to parameterize these two ditch routing methods. Suspended solids transport and nutrient reaction processes are represented in the dynamic ditch model mainly following the QUAL2K model. Specifically, the net settling rate of inorganic suspended solids during their transport through the ditches is directly calculated, instead of estimating the entrainment and deposition fluxes separately, which is a simplification that has been widely adopted in water quality models. Reaction processes of nutrients represented in the model include decay of particulate organic matter to dissolved organic matter (N and P), decay of dissolved organic matter (N and P) to inorganic N and P, partitioning of the inorganic P on inorganic suspended solids and sequential settling, and nitrification and denitrification processes. Aspects of the disclosure follow similar governing equations of those reaction processes, which have been extensively used in water quality models for nutrient simulation. The dynamic river transport model takes the output fluxes of the ditch model as inputs. Similar to the ditch model, the water flow in the river channels can be simulated using either the Muskingum method, Muskingum-Cunge method, or diffusive wave method in the model. The sediment transport module in the dynamic river model considers complex in-stream processes such as deposition, bank and bed erosion, re-entrainment, and settling. The nutrients processes are mostly similar to those in the ditch dynamic model. And the difference is that the transport of attached nutrients with channel flow is not conservative since the river dynamic model accounts for the exchange of suspended sediment between the water column and channel bed.

For the data-driven models, statistical or machine learning models are built to establish the relationship of simulated water, sediment, nutrient and pollutant fluxes at a high spatial resolution versus observed discharge, sediment, nutrient and pollutant loads (or concentrations) at a watershed outlet. The watershed scale observations can be either from existing gauges supported by the federal or state agencies or new IOT sensor network. For the latter, IOT sensors can be installed at different levels of watershed outlets to monitor discharge rate, sentiment, nutrient and pollutant loads (or concentrations). Besides the time series data of simulated water, sediment, nutrient and pollutant fluxes at high resolution and the observed discharge, sediment, nutrient and pollutant load (or concentrations) at watershed scale, other feature data, including (but not limited to) weather forcing, soil properties, land use and land cover data, and human management characterization data can also be used when building the data-driven models. The data-driven models can be built using traditional statistical methods, machine learning, deep learning, and/or physics-guided machine learning approaches. The trained relationships can be directly coupled with a high-resolution process-based model to scale the high-resolution water, sediment, nutrient and pollutant fluxes up to the whole watershed scales.

1.4 Model-Data Fusion Framework

This invention includes a generic model-data fusion framework for agricultural sustainability assessment. This model-data fusion framework enables ingesting multi-source observation data to constrain the process-based models, including but not limited to those from satellite/airborne/proximal remote sensing, wireless sensor network (WSN), Internet of Things (IoT), Eddy-Covariance (EC) flux towers, ground surveys, in-situ field experiments, standard streamflow gauges, and governmental statistical data. Model-data fusion described here includes model validation, model parameter calibration with observations data or data assimilation for model state and/or parameter updating, and physics-guided machine learning. Before using observations to constrain models, the sensitive parameters in the model are screened out by conducting model sensitivity analysis, such as both qualitative (such as Morris type) and quantitative (such as Sobol type) analyses. Parameters related with crop growth (e.g., phenology, photosynthesis, and carbon/nutrient allocation), soil parameters (e.g., hydraulic conductivity), tile drainage efficiency, ditch and river routing (Manning's roughness coefficient and kinetic rates) can be partially or fully considered in the calibration depending on the calibration purpose. Only the most sensitive parameters are calibrated to obtain optimized parameter set(s). The mathematical method for calibration can be either global optimization algorithms (including but not limited to genetic algorithms, evolutionary algorithms, and Markov Chain Monte Carlo algorithms) or Bayesian inference algorithms.

The landscape modeling is challenging because there is a large spatial heterogeneity caused by soil types, management practices, crop conditions. Besides accurate and high-resolution input data for the modeling, ensuring there is a local constraint is critical to achieve high accuracy and realistic simulation at the field scale in the process-based modeling. Notable, location-specific model parameters can include:

(1) plant physiological parameters that are varying across time and space and also genetically, but are generally not dynamically modeled in the current model, such as plant photosynthetic capacity, and grain-filling rate; and

(2) local soil properties, including soil hydrological, tile drainage efficiency, and some biogeochemical properties. Though in some cases we have an available soil database, it is well known that these soil data can have large errors at a specific local area. Using observations to further constrain these soil related parameters can critically reduce the uncertainties.

Using high-resolution local constraints for modeling across the landscape is however not the case in the previous work, due to the following reasons: (i) Lack of high-resolution field-scale observations for everywhere; (ii) Heavy computation needs to fuse local observation with models. Without such a local constraint, model simulations can be significantly deviating from reality. For the applications that field-level accuracy is one major target, for example, soil carbon credit is accrued at the field scale, then ensuring accurate field-level quantification is a must which makes the local constraint a prerequisite.

Though there are multiple sensors and data sources available for model constraints, high-resolution satellite data provide ubiquitous coverage and should be used in this case. In the IMAPS framework, location-specific model parameters, such as plant photosynthetic capacity and grain-filling rate, can be constrained using field-scale daily leaf area index, evapotranspiration and gross primary productivity estimates, and crop yield. Prior distribution of those model parameters will be derived from existing soil dataset (such as gSSURGO) and literature-based meta-analysis. For soil parameters which are spatially varying, aspects of the disclosure will calibrate a scalar factor applied to the original parameter values derived from existing soil dataset (such as gSSURGO) assuming the scalar factor is constant at watershed scale. For crop, tile drainage efficiency, and routing parameters, we assume they are homogeneous at field or watershed scale (e.g., HUC12). This approach largely reduces the risk of being overwhelmed by large parameter numbers, and makes the parameter calibration scalable. To overcome the computational limit, machine learning or deep learning-based emulators or surrogate models can be built by training with simulated databases by the original process-based models.

Besides parameter calibration, variational or sequential data assimilation methods can be used to update the model state or update the model state and parameters jointly or simultaneously. Physics-guided machine learning is another approach for data-model integration, which can integrate the strengths of both process-based models and data-driven models. Multiple strategies of physics-guided machine learning (PGML) can be implemented to build the data-model fusion models, including pre-train machine learning models with physical-model-simulated database, reconstructing causal networks among different variables, mapping variable dependence structure (variable sequence) and variable nature (state or flux) in the physical models, and adding real physical constraints (such as real physical laws like mass balance) into the machine learning models.

1.5 Hypothetical Scenario Assessment

The modeling platform according to aspects of the disclosed invention enables hypothetical scenario assessment of the impacts of different management practices and climate change scenarios on both crop production and environmental sustainability. Specifically, the following scenarios and their combinations provide an inconclusive list of options that can be assessed using this modeling platform: (1) crop rotation: such as continuous corn and soybean, and corn-soybean rotation; (2) tillage: no-till, reduced tillage, versus conventional tillage; (3) cover crops: with versus without cover crops and varied cover crop types and growing windows; (4) nitrogen fertilizer applications: application time (conventional fall or spring application versus spring application with sidedressing), and different application amounts and with or without inhibitors; and (5) tile drainage: free tile drainage versus controlled tile drainage; (6) different projected climate change scenarios; (7) other human management practices. The modeling platform also enables trading water credits (quantity and quality) and helping design regional and national policies for controlling nutrient loss and water quality.

1.6 Cyberinfrastructure

The cyberinfrastructure according to any of the aspects and/or embodiments of the disclosure includes a comprehensive computer database, a pipeline to run the IMAPS model and a visualization website portal. The computer database is developed to store and archive all the input and output data of the IMAPS modeling platform. The running pipeline of the IMAPS model offers a one-click solution to run the whole model with a proper model configuration file. The running pipeline can also be scheduled to run the IMAPS model automatically for operational simulation. The visualization website portal is developed to efficiently communicate the simulation results of the IMAPS model with users.

1.7 Examples

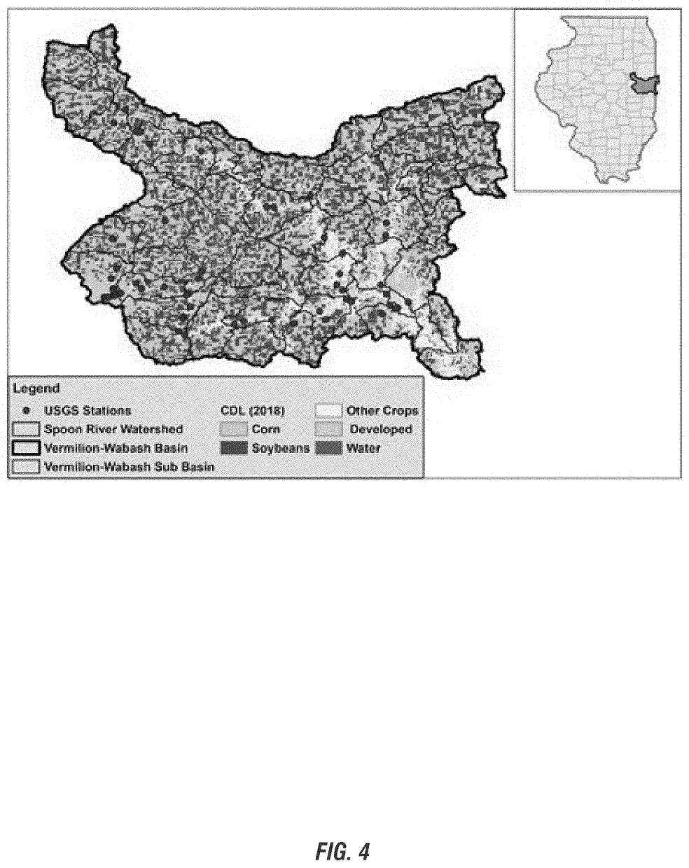

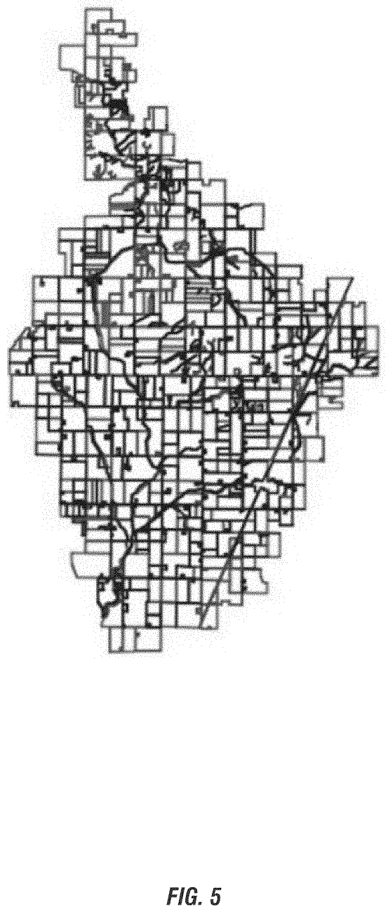

A demonstration study of the IMAPS modeling framework was conducted over a 12-digit hydrologic unit code (HUC12) agricultural watershed, Spoon River watershed, in east-central Illinois (FIG. 4). The Spoon River watershed is an agricultural headwater with a drainage area of 43 square miles (27520 acres or about 111 square kilometers). This watershed is a typical landscape in the U.S. Midwest, with about 50% and 42% land for corn and soybean cultivation, respectively. The ditch network derived using our algorithm over this watershed is shown in FIG. 5.

According to at least one example, ecosys was used as the point-scale model and it was coupled with the SSD scheme and the ditch-river routing model. Ecosys is an advanced process-based ecosystem model that simulates the field-scale energy-water-carbon-nutrient dynamics. Compared with typical cropping system models, ecosys is a more mechanistic model as it explicitly solves energy-water-carbon-nutrient balances and transfers within the soil-canopy-atmosphere continuum. Ecosys simulates root-to-leaf plant hydraulics, photosynthetic biochemistry, and processes related with soil biogeochemical cycling, such as microbe-plant nutrient interactions, and impacts of major management practices. Uniquely, ecosys is one of the very few models that explicitly simulates the coupled soil carbon-nitrogen-phosphorus cycles. Previous works using ecosys have fully demonstrated its capabilities in simulating soil nitrogen cycle, N2O emission, long-term soil organic matter trend, and impacts of different tillage practices.

According to at least one example, the ecosys model was on each individual field with the field boundary delineated using our own deep learning algorithm. Sub-field heterogeneity was explicitly considered by adopting an approach similar to Corteva's Environmental Response Unit (ERU) in which high-resolution grids (˜30 m) over any specific field were clustered into several categories by considering soil and topographical characteristics, and satellite-based crop features (vegetation indices, leaf area index, and yield estimations). Ecosys was used to conduct simulations over those clusters, instead of all high-resolution grids within a single field, and the model outputs for clusters can be mapped back to high-resolution gridded maps through post-processing. This clustering-based approach offers a computationally efficient and feasible way to consider the sub-field heterogeneity in field-scale model simulations. Specifically, we used gSSURGO soil data (30 m), SRTM DEM data (30 m), VIs, LAI, and yield based on STAIR satellite fusion data (Luo et al., 2018) for subfield clustering. Some field management information was derived from satellite products, such as crop type from USDA NASS Cropland Data Layer (CDL), sowing/harvest date, and tillage type.

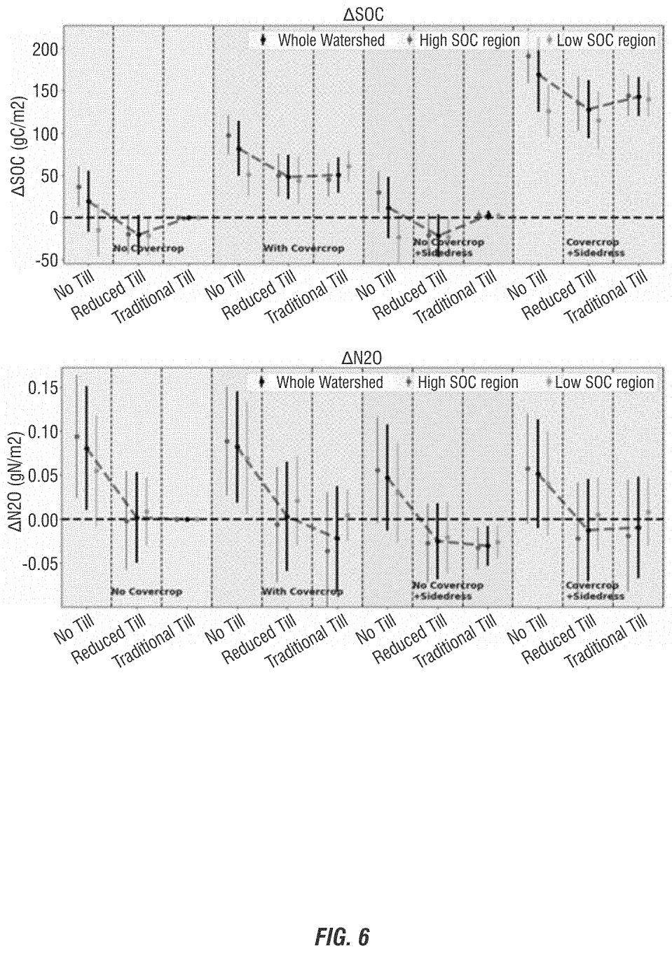

An example of the sustainability assessment results is given in FIG. 6. In this example, the IMAPS modeling platform was used to assess the impacts of different land management practices over agricultural landscapes. The impacts of different conservation practices (i.e., changing tillage type, planting cover crops, applying fertilizer side-dressing) on environmental sustainability were assessed. For the simulations, North American Land Data Assimilation System (NLDAS-2) hourly meteorological data and gSSURGO soil data were used as inputs. Multiple satellite-based measurements, including GPP and yield, were used to constrain the model. The simulations were ran from 1979 to 2018 using corn-soybean rotation without irrigation (the major plant strategies within this area). The period between 1979 and 2000 was used for model spin up with no-till and no cover crop, while different land management practices were applied during 2001-2018. Finally, the impacts of the different land management practices on soil carbon sequestration and N2O emission were assessed using the simulations during 2015-2018. The results show that planting cover crops has significant benefits for soil carbon sequestration and conservation tillage may increase the N2O emission in both the high and low SOC conditions.

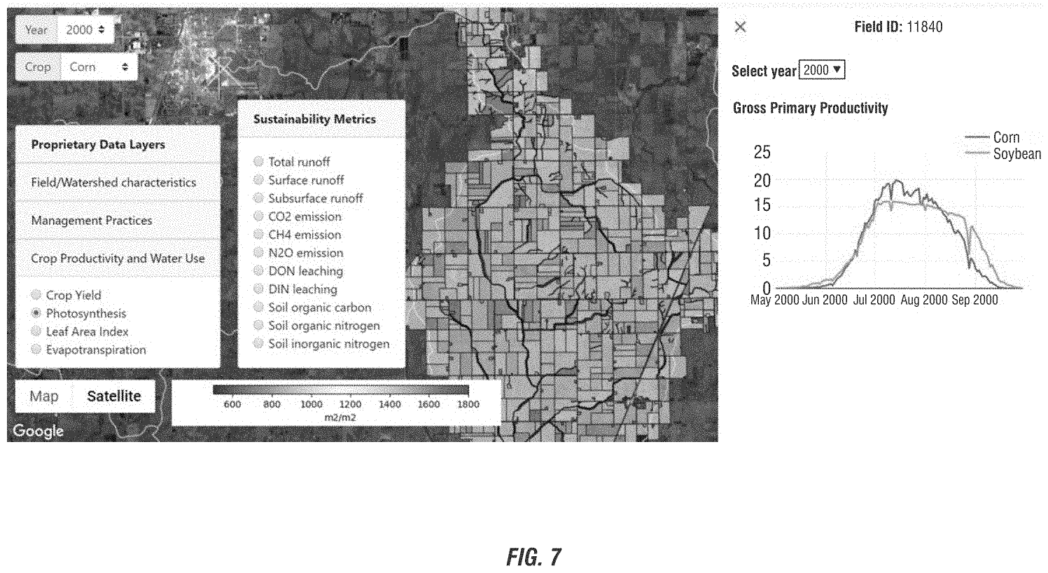

FIG. 7 gives an example of the dashboard in the visualization portal to communicate sustainability assessment results with users. In this example dashboard, satellite data layers and sustainability metrics are shown in two different data layer lists. The data layers for sustainability metrics are all from the observation-constrained IMAPS model.

### Example 2: A Scalable and Cost-Effective Precision Irrigation Scheme with Field-Scale ET Products Based on Supply-Demand Dynamics

Field-scale evapotranspiration (ET) and soil moisture are critical for precision irrigation at fine scales. The most widely used approach for irrigation scheduling (i.e., when and how much water to irrigate) is solely based on soil moisture, which is usually estimated from soil water balance with crop water use (i.e., ET). ET is usually obtained from coarse-resolution satellite ET products and/or using Penman-Monteith equation and the crop coefficients with the meteorological data from nearby weather stations, while soil moisture is usually provided by soil water balance and/or soil moisture sensors directly. However, the traditional approaches for field-scale ET and soil moisture for irrigation scheduling is expensive and/or sometimes low-accuracy.

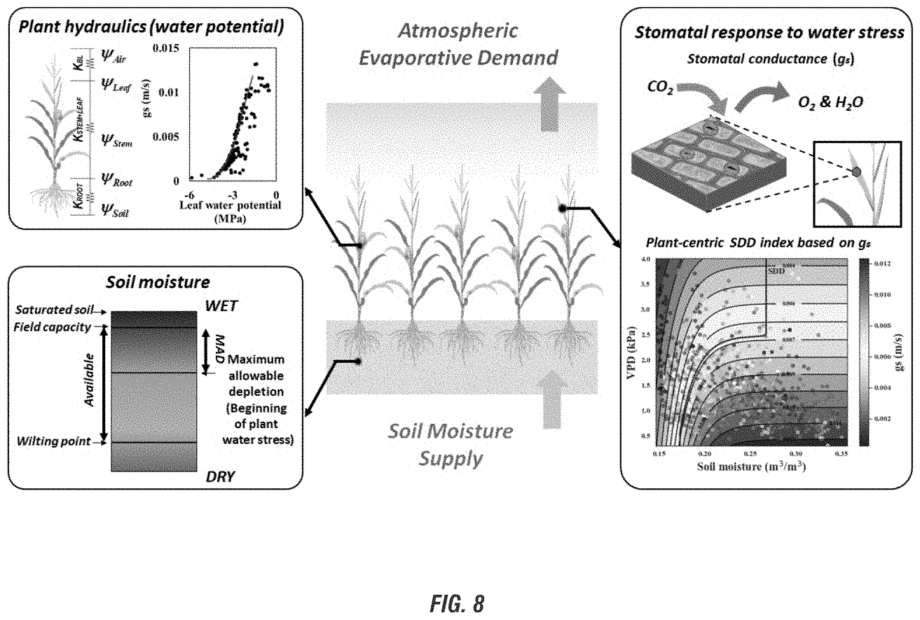

Furthermore, soil moisture deficit and atmospheric aridity (high vapor pressure deficit, VPD) both can cause reduction of agroecosystem productivity. Traditionally, agricultural irrigation management has primarily focused on soil moisture deficit (plant water supply) to quantify plant water stress (e.g., maximum allowable depletion, MAD in FIG. 8), but largely neglected plant water demand from atmospheric aridity. It is argued that because plant water stress is co-limited by soil moisture supply and atmospheric evaporative demand (see, e.g., FIG. 8), a plant-centric plant water stress index should be defined holistically based on the interplay between soil moisture supply, atmospheric evaporative demand, and plant physiological regulations, such as plant hydraulics (leaf water potential) and stomatal response (stomatal conductance) in FIG. 8, for agricultural irrigation management.

At first, aspects of the disclosure can provide accurate field-scale ET by using a satellite-driven water-carbon-energy coupled biophysical model BESS (Breathing Earth System Simulator, BESS) combined with the STAIR fusion data, called BESS-STAIR ET products with a high spatiotemporal resolution (daily, 10-30 m) under all-sky conditions. It can also be calculated by observed leaf area index (LAI), vapor pressure deficit (VPD), and air temperature (Ta) from the CropEyes sensor. The operational high spatiotemporal resolution ET can be assimilated into a hydrologic model to calculate simulated soil moisture with high accuracy.

Furthermore, plant water stress is defined considering the joint contribution of soil water supply (root-zone soil moisture) and atmospheric water demand (VPD), mediated by plant physiological regulations. The “rule-of-thumb” irrigation triggering threshold value (e.g., 50% of MAD) based on soil moisture is replaced by dynamic irrigation triggering threshold function of both soil moisture and VPD. This dynamic precision irrigation scheme based on accurate high-resolution ET is water-efficient and can be implemented at every individual field in large regions, such as county, state, or nation.

In addition, irrigation estimation at high spatiotemporal resolution is coupled with the dynamic precision irrigation scheme. If farmers do not provide the past irrigation decisions to the irrigation systems, the irrigation decisions could be inferred through the proposed model-data fusion framework based on data assimilation of ET.

2.1 Framework

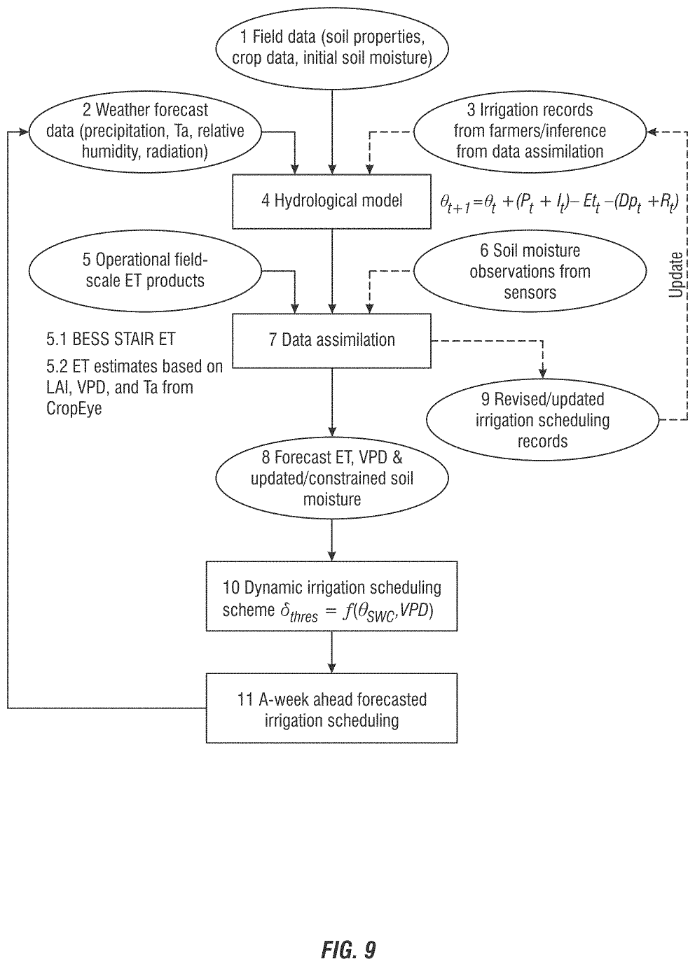

The framework of the scalable and cost-effective precision irrigation scheme is shown in FIG. 9. There are 11 sub-modules. As shown in FIG. 9, the sub-modules may be:

1 Field data. The crop data (such as planting and harvest day, fertilizer, tillage, etc), soil properties, and initial soil moisture should be provided as field data for hydrological model (4).

2 Weather forecast data. Real-time weather forecasts up to 7 days (including precipitation, air temperature, relative humidity, radiation, wind speed, and so on) can be generated and provided as model inputs (4) to simulate the forecasted ET, VPD, and soil moisture.

3 Irrigation records from farmers/inference from data assimilation. If farmers provide the applied actual irrigation records, the actual irrigation records can be set as the model inputs (4). Besides, if the irrigation scheduling records cannot be obtained from farmers, the missing irrigation records can be inferred from field-scale ET products, data assimilation, and the hydrological model.

4 Hydrological model. With the field data (1), real-time weather forecast (2), and possible irrigation records (3) performed as model inputs, the hydrological model can provide the model simulations of evapotranspiration (ET), soil moisture, deep percolation, and surface/subsurface runoff based on soil water balance.

5 Operational field-scale ET products. The real-time operational field-scale ET products can be provided as model constraints to improve the accuracy of model simulations (4). There are two approaches to provide the operational field-scale ET products. The first approach is using a satellite-driven water-carbon-energy coupled biophysical model BESS (Breathing Earth System Simulator) combined with the STAIR fusion data, called BESS-STAIR ET products with a high spatiotemporal resolution (daily, 10-30 m) under all-sky conditions. The second approach is to calculate the field-scale ET products based on the field-scale observations of leaf area index (LAI), vapor pressure deficit (VPD), and air temperature (Ta) from the CropEyes sensor.

6 Soil moisture observations from soil moisture sensors. If the field is installed with the soil moisture sensors, the real-time soil moisture observations can be provided as model constraints to improve the accuracy of model simulations (4).

7 Data assimilation. The real-time operational field-scale ET products (5) and possible soil moisture observations (6) can be assimilated into the hydrological model (4) to improve the accuracy of model simulations during the forecast horizon.

8 Forecasted ET, VPD & updated/constrained soil moisture. The forecasted ET, VPD, and soil moisture up to 7-days can be obtained from the hydrological model (4) and the real-time weather forecast (2). The simulated soil moisture from hydrological model (4) can be updated or constrained by the assimilation of the real-time operational field-scale ET products (5) and possible soil moisture observations (6).

9 Revised/updated irrigation scheduling records. If farmers did not provide the irrigation scheduling records (3) and there is no precipitation, the operational field-scale ET products (5) and soil moisture observations (6) have a large increase (larger than a threshold), while ET and/or soil moisture simulations do not have the increasing trend, we assume that there is one missing irrigation records that farmers do not provide to the precision irrigation systems. ET and/or soil moisture observations can be assimilated into the hydrological model (4 and 7) to infer the missing irrigation records in real-time.

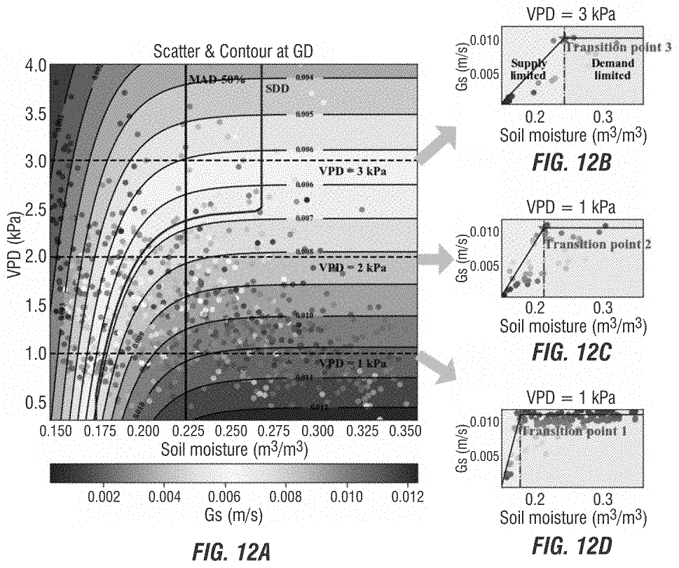

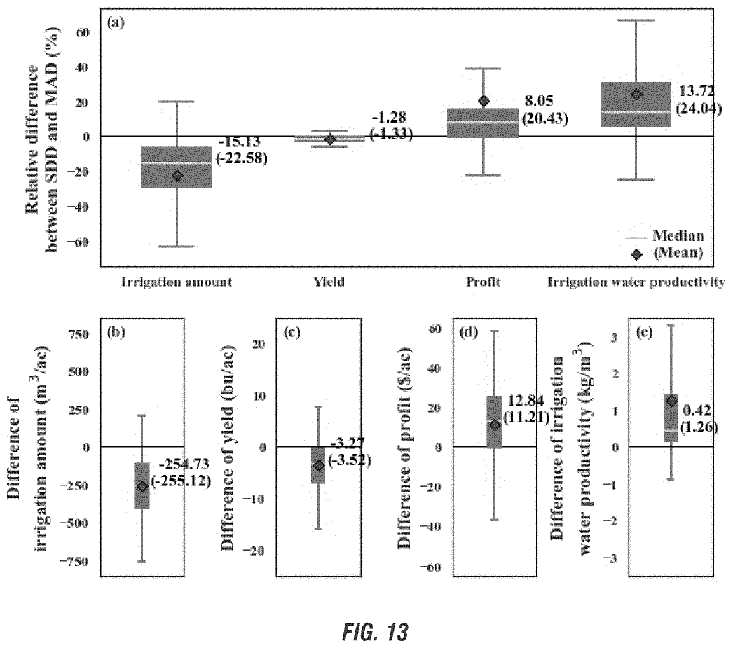

10 Dynamic irrigation scheduling scheme. Plant water stress is defined considering both soil moisture and VPD. The traditional irrigation triggering rule is solely based on soil moisture (e.g., 50% of MAD performed as triggering threshold value δ [symbol] =f(θ [symbol] )), largely neglecting plant water stress from atmospheric aridity. Dynamic irrigation triggering threshold function of soil moisture and VPD (δ [symbol] =f(θ [symbol] ,VPD)) can be defined based on supply-demand dynamics from the aspects of leaf water potential and/or stomatal conductance (FIGS. 8 and 12). Plants can have water stress even with high soil moisture but under high VPD; while plants may not have water stress when soil moisture is relatively low and VPD also happens to be low.

11 A-week ahead forecasted irrigation scheduling. With the forecasted ET, VPD and updated/constrained soil moisture (8), a-week ahead irrigation decisions can be provided using the dynamic irrigation triggering threshold function of soil moisture and VPD (10).

The whole process can perform as a closed-loop control system for each time period during the crop growing season.

2.2 Case Study

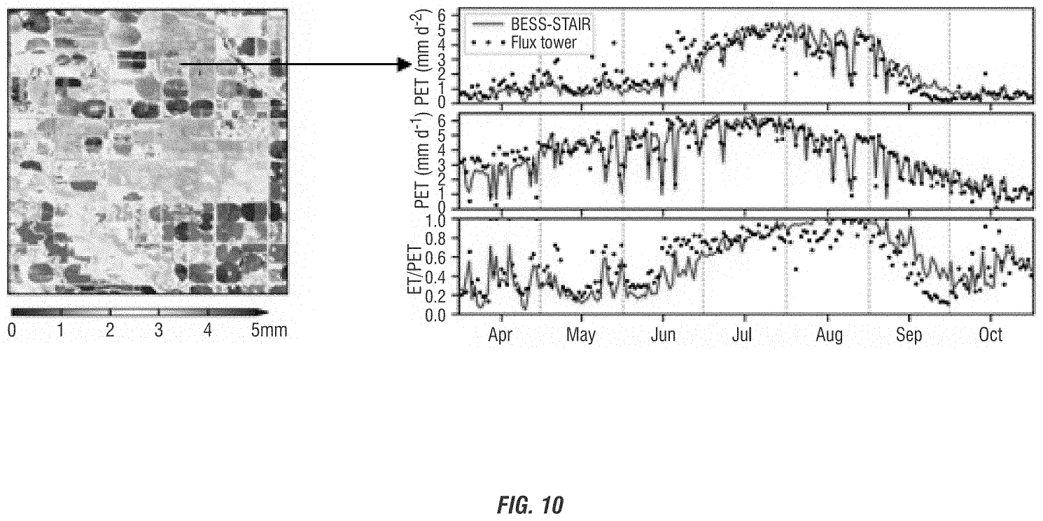

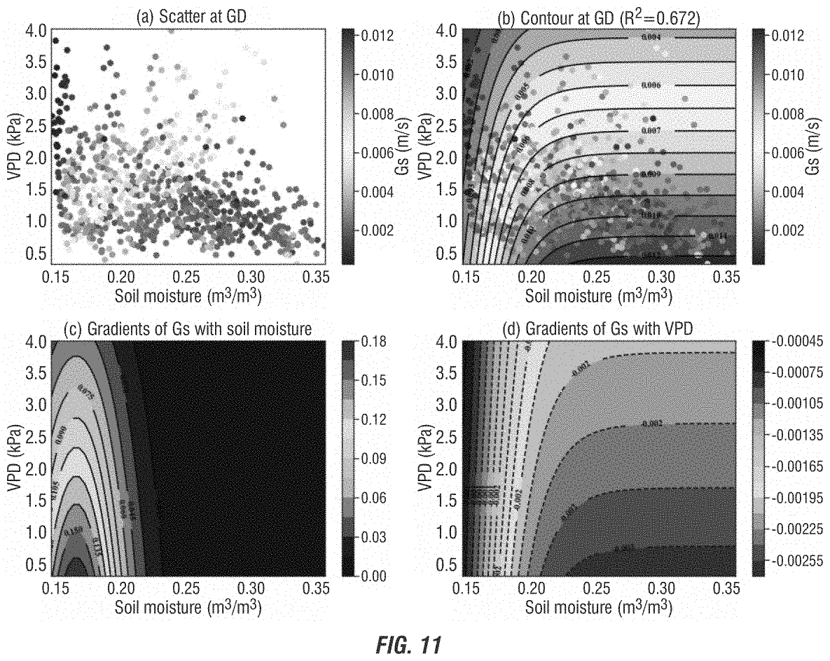

(1) The BESS STAIR ET products have been generated and tested its performance in Nebraska (FIG. 10) and the broader corn belt regions. BESS model itself has been tested at the global scales for different ecosystems.

(2) The precision irrigation scheme based on soil moisture and VPD at field-scale is currently implemented in Python. Examples have tested the performance of a new precision irrigation scheme from the aspect of stomatal conductance in Nebraska. The traditional constant irrigation triggering threshold (e.g., 50% of MAD, the solid black straight line in FIG. 12) can be replaced by the dynamic irrigation triggering threshold function of soil moisture and VPD based on supply-demand dynamics (SDD, the blue curve in FIG. 12). The stomatal conductances are primarily limited by water supply (soil moisture) and water demand (VPD), with the simulations from an advanced process-based model, Ecosys (FIG. 11). The relationship among soil moisture, VPD, and stomatal conductance can be fitted to develop the relationship of Gs=f (VPD, Soil moisture). In one realization, the system can use Eq (1), thus the contours of stomatal conductance as a function of VPD and soil moisture (FIGS. 11 and 12). Plants can have water stress even with high soil moisture but under high VPD; while plants may not have water stress when soil moisture is relatively low and VPD also happens to be low. Thus, the dynamic irrigation triggering threshold values can be determined using the fitted contour that stomatal conductance cannot decrease to the critical stomatal conductance (e.g., 0.007 m/s) (i.e., the blue curve in FIG. 12). The critical stomatal conductance is treated as an equilibrium between the soil water supply (soil moisture) and the atmospheric water demand (VPD), i.e., the transition points in FIGS. 12b, 12c, and 12d. The location of the transition point varies with soil moisture and VPD (FIG. 12). The transition point moves to lower soil moisture under low VPD, as the demand of the equilibrium point is decreased (FIG. 12d); while it moves to higher soil moisture under high VPD due to the increased demand of the equilibrium point (FIG. 12b).

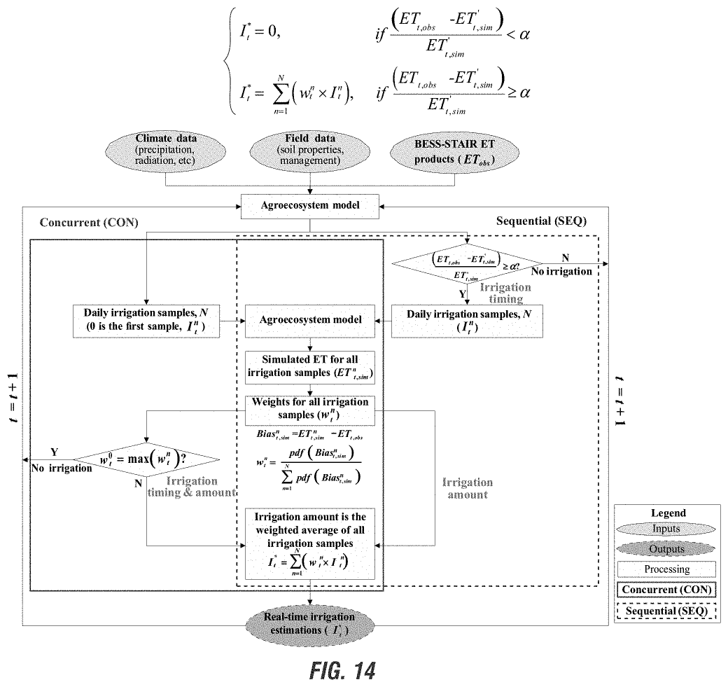

The proposed high spatiotemporal resolution estimation of irrigation timing and amount at daily and field-scale is currently implemented in Python. The system and variables have tested the performance of the proposed irrigation estimation based on the model-data fusion framework at two irrigated fields in the eastern and western Nebraska. Model-data fusion approach usually integrates data and models to improve the accuracy of model simulation. There are multiple model-data fusion methods, such as data assimilation and model calibration. The advanced agroecosystem model (ecosys) was calibrated first, then field-scale ET observations with daily interval was assimilated into the well-calibrated ecosys model for high spatial-temporal resolution estimation of irrigation timing and amount at daily and field-scale (FIG. 14). Two methods with different configurations for irrigation timing and amount, including concurrent (CON) and sequential (SEQ), based on the model-data fusion framework were proposed. Data assimilation is one typical approach of model-data fusion, which could effectively correct the state estimations due to the uncertainty from models and observations. Particle filtering, one of the sequential data assimilation schemes based on Monte Carlo algorithms, was used. The key idea was to determine the posterior density function by a set of random samples with associated weights. To simplify its process, a resampling scheme was not adopted.

Daily irrigation events with different amounts from random distribution with the given ranges were the particles of particle filtering (Eq. 2). The first particle with 0 mm was always set to represent no irrigation for the targeted day. All the particles with different irrigation amounts would be incorporated into the advanced agroecosystem model, ecosys, to get ET simulations for different particles. Then, the associated weights (wₜⁿ) for each particle could be calculated as the percentages of probabilities (pdf(Bias_{t,sim}ⁿ) based on the given bias distribution and calculated bias between ecosys simulations and observations of ET to remove the systematic bias, i.e., bias correction (Eqs. 4 and 5). Finally, the irrigation amount could be estimated as the weighted average of all the particles with their associated weights (Eq. 6).

$$\begin{matrix}{I}_{t}^{n} ∈ [ 0 , β \times {I}_{max} ] , m = 1 , L , N & ( 2 ) \\ {I}_{max} = \frac{capacity \times 24 \times 60 \times 25.4}{{S}_{field} \times 27154} & ( 3 ) \\ {Bias}_{t , sim}^{n} = {ET}_{t , sim}^{n} - {ET}_{t , obs} & ( 4 ) \\ {w}_{t}^{n} = \frac{pdf ( {Bias}_{t , sim}^{n} )}{{\sum }_{n = 1}^{N} pdf ( {Bias}_{t , sim}^{n} )} & ( 5 ) \\ {I}_{t}^{*} = {\sum }_{n = 1}^{N} ( {w}_{t}^{n} \times {I}_{t}^{n} ) & ( 6 )\end{matrix}$$

where Iₜⁿ was the irrigation particle n at time period t (mm/d); Iₘₐₓ was the maximum allowed irrigation amount (mm/d), usually determined by the capacity of pumping well (gallon per minute, gpm) and the field area (S_{field}, acre) (Eq. 3); β was the parameter needed to be calibrated for irrigation ranges; N was the particle size; Bias_{t,sim}ⁿ was the bias of ET between model simulation (ET_{t,sim}ⁿ, mm/d) with the irrigation particle n and observation (ET_{t,obs}, mm/d) at time period t (mm/d); pdf(Bias_{t,sim}ⁿ) was the probability of bias for the irrigation particle n at time period t; wₜⁿ was the weight for the irrigation particle n at time period t; Iₜ* was the estimated irrigation amount at time period t (mm/d).

There were two methods with different configurations for irrigation timing and amount, including concurrent (CON) and sequential (SEQ), based on the model-data fusion framework (FIG. 14). CON determined irrigation timing and amount simultaneously based on all the irrigation particles and their associated weights. Specifically, if the weight of the first particle (wₜ⁰) was maximum among all the particles, CON would claim that there was no irrigation event on that day. Otherwise, the irrigation amount was determined as the weighted average of all the irrigation particles. Different from CON, SEQ determined irrigation timing at first based on the relative bias of ET, i.e., there was no irrigation event if the relative bias of ET between observation and simulation was smaller than the set threshold (α) (Eq. 7). If the relative bias of ET reached the set threshold, the irrigation amount was the weighted average of all the irrigation particles. It needed to be noted that irrigation duration (dT) for each irrigation event was complicated by multiple factors, such as irrigation systems, and climate status. For example, center pivot irrigation systems usually took several days to finish one cycle of an irrigation event at one field, and the irrigation might stop when there was a rainfall event exceeding a certain amount. Thus, there were two common parameters (irrigation range, β, and irrigation duration, dT) needed to be tuned for CON and SEQ, while another parameter (relative bias threshold, α) was also needed to be tuned for SEQ.

$$\{ \begin{matrix}{I}_{t}^{*} = 0 , & if \frac{( {ET}_{t , obs} - {ET}_{t , sim}^{′} )}{{ET}_{t , sim}^{′}} < α \\ {I}_{t}^{*} = {\sum }_{n = 1}^{N} ( {w}_{t}^{n} \times {I}_{t}^{n} ) , & if \frac{( {ET}_{t , obs} - {ET}_{t , sim}^{′} )}{{ET}_{t , sim}^{′}} \leq α\end{matrix} \qquad ( 7 )$$

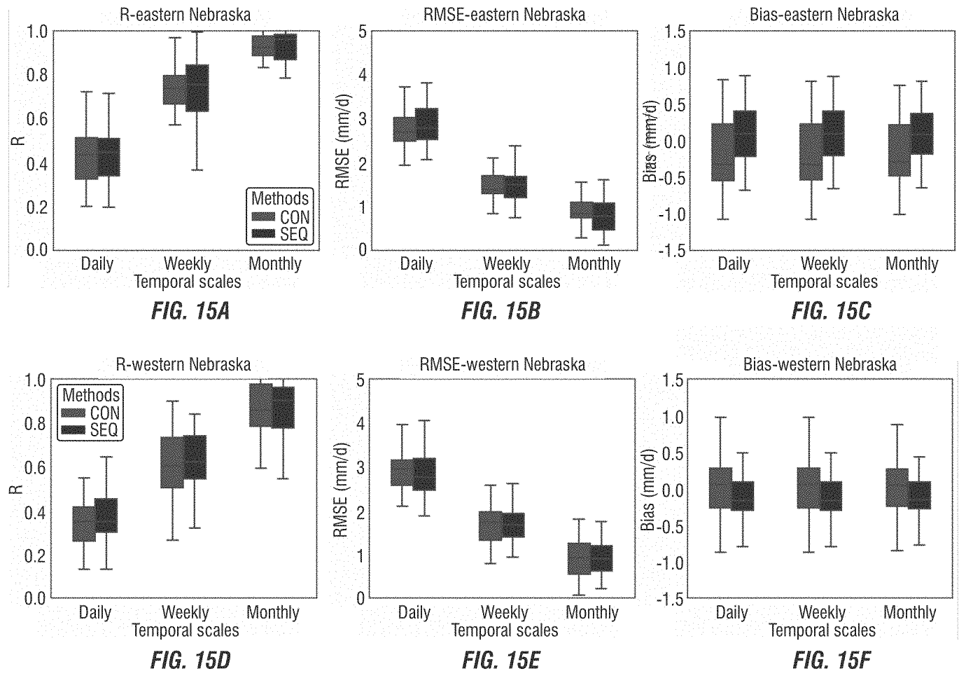

CON and SEQ methods were applied for high spatial-temporal resolution (field-scale and daily) irrigation estimation with ten replicates at two sets of irrigated fields in the eastern and western Nebraska. Bias correction was applied in particle filtering to adjust the systematic bias between ecosys simulations and observations of ET during irrigation estimation. Three statistical indexes (R, RMSE, and Bias) between irrigation estimations and records were calculated for each site-year with different temporal scales (daily, weekly, and monthly). CON and SEQ performed better on high spatial-temporal resolution estimation of irrigation timing and amount in the eastern Nebraska than those in the western Nebraska, i.e., higher R and lower RMSE and Bias in the eastern Nebraska (FIGS. 15-A-F). The performance of CON and SEQ for irrigation estimation largely depended on the accuracy of model simulations and observations of ET.

For the performance comparison between CON and SEQ, SEQ performed better than CON in the eastern Nebraska, while there was little difference between CON and SEQ in the western Nebraska (FIGS. 15A-F). The assumption, that there was an incremental increase of ET due to irrigation, was embedded in the SEQ method. The consequent incremental increase of ET due to irrigation could be captured by the eddy covariance observations in the eastern Nebraska, while the satellite-based BESS-STAIR dataset used in the western Nebraska could not capture this quick variation, but it could be improved through incorporating land surface temperature in the future. For the performance of CON and SEQ on different species, there was little difference between maize and soybean.

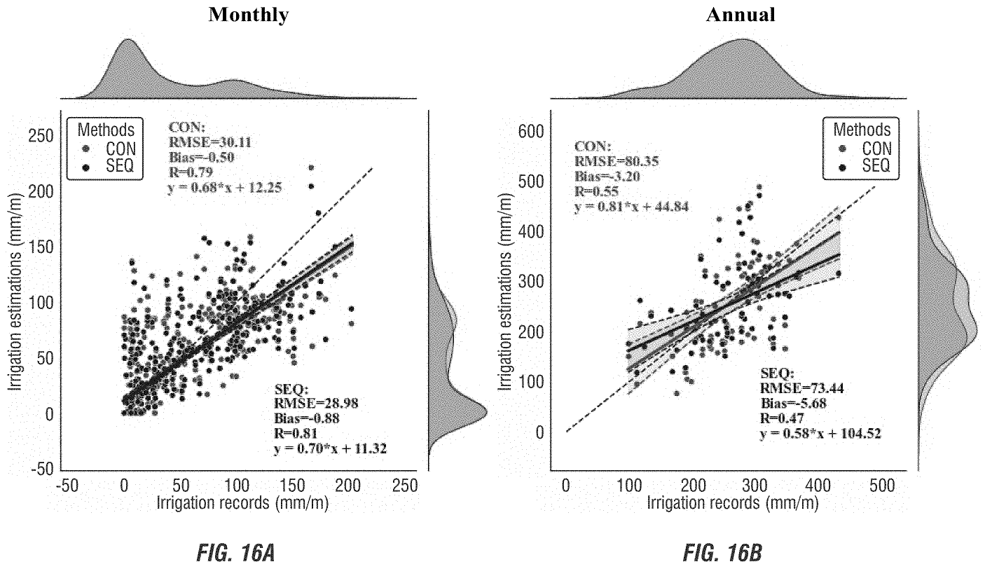

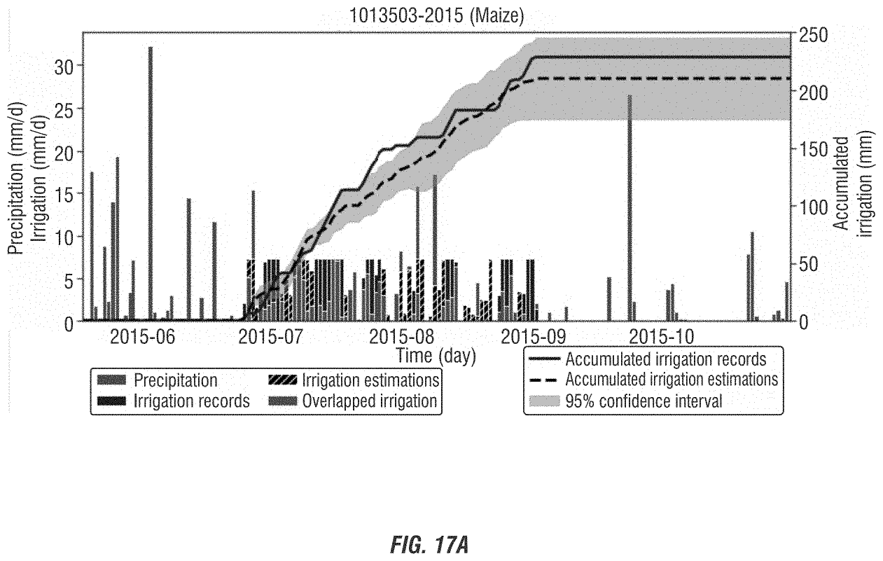

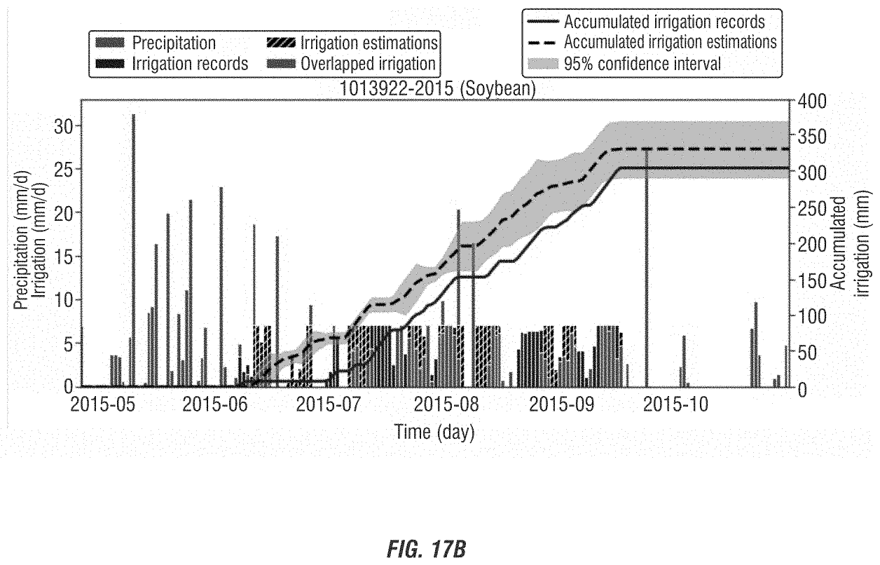

The monthly and annual irrigation estimations of CON and SEQ matched well with the irrigation records for all the site-years in Nebraska (FIG. 16). For the monthly scale, the Pearson correlation coefficients of CON and SEQ were 0.79 and 0.81, respectively, with the bias of −0.50 mm/m and −0.88 mm/m. There were bimodal distributions with the peak around 0 and 100 mm/m for irrigation estimations and records. For the annual scale, the 95% confidence interval of the regression lines between irrigation estimations and records covered the 1:1 line, with the Pearson correlation coefficients of 0.55 and 0.47 for CON and SEQ, respectively. Taking field (1013503) and field (1013922) in 2015 in the western Nebraska as examples for maize and soybean, CON and SEQ methods could detect most of the daily irrigation records (the overlapped irrigation in FIGS. 17A-B), but also had some missing or redundant irrigation events.

### Example 3: A Method of Generating and Refining Crop Types Classification and Acreage Forecast During the Crop Growing Season (BlueBird)

An effective real-time crop cover classification prediction is essential to real-time large-scale crop monitoring. High resolution satellite optical data containing distinguishable signals of different crop types have been used by recent crop cover classification studies. However, existing works that merely use satellite information fail to reach a high accuracy, especially in the early growing season (e.g., before July) because of lacking informative satellite scenes that can be used to effectively distinguish crops. In this section, what is presented is a deep-learning-based method, herein named BlueBird, to accurately classify crop cover types in real-time at the national scale. BlueBird consists of three sub-models: prior-knowledge model, real-time optical model, and real-time weight model. Historical planting information, sequence of planted crop types in past years, is incorporated into the prior-knowledge model to improve the performance, especially in the pre and early season when satellite images do not contain distinguishable crop signals.

Available satellite optical data is used by the real-time optical model to extract spatial and temporal information that can be used to classify the crops. Finally, BlueBird integrates historical crop planting information with spatial and temporal patterns discovered from satellite time series using a trainable real-time weight model that evolves over time, thereby allowing the satellite-based model to be increasingly dominant as more observation data are available. Also proposed is a national acreage model based on BlueBird's real-time prediction to predict the national acreage of two major crops, corn and soybean. Leave-one-year-out validations have been conducted in the whole U.S. Corn Belt from 2014 to 2019 to evaluate the real-time performance of BlueBird. F1 score maps have been generated that compare BlueBird's predictions with CDL and scatter plots that compare BlueBird's county-level acreage with NASS's ground truth to demonstrate the large-scale effectiveness. In the map of June 1, it is shown that corn belt counties where corn and soybean are dominant crop types generally reach ˜0.8 F1 score. Same promising results can be concluded from the scatter plot of June 1, that for both corn and soybean, most years reach a r\hat{ }2 above 0.85. From the accuracy map and scatter plot on August 30, the significant improvement from initial predictions to end-of-season predictions are identified. In the detailed analysis of Champaign, Ill., BlueBird achieves F1 scores (˜0.88) on June 1 for all the validation years and end-of-season F1 scores above 0.95 for all years except 2019 when historic flooding and precipitation happens. BlueBird's predictions are used to evaluate the national acreage model using the ground truth released by NASS. Error of Corn acreage has a RMSE of 2.12% on June 1 and a RMSE of 1.36% on August 30. Error of soybean acreage (2014 to 2018) has a RMSE of 1.70% on June 1 and a RMSE of 0.85% on August 30. The extensive results demonstrate that BlueBird is capable of generating highly accurate real-time crop cover in national-scale and the national acreage model is effective in predicting corn and soybean acreages.

3.1 Satellite Remote Sensing

Remote sensing is the observation of an object without physically touching it. Satellite remote sensing is the remote sensing method that uses satellites as the platform to carry sensing equipment. It generally provides the observations of four fundamental properties: optical color, temperature, roughness, and distance. One of the significant advantages of satellite remote sensing is its large area coverage that offers a feasible way to conduct large scale study. Besides, satellite remote sensing allows for easy collection of data over a variety of scales and resolutions. The common spatial resolutions of satellite observations range from sub-meter to 30 km. Spatial resolution and temporal frequency trade off is a long-lasting dilemma in the field of remote sensing. Low-resolution satellite missions are able to have world-wide daily observations while high-resolution satellite missions generally have a high latency. Satellite remote sensing offers unique insights into a wide range of subjects including geology, oceanography, climatology, meteorology, precision agriculture.

3.2 Machine Learning of Real-Time Crop Cover Classification

Land cover is the physical material at the surface of the earth including crops, grass, forest, water, developed space, etc. Among all the land cover types, crop types are the main focus of most types of research. Crop cover classification is a classic question in the remote sensing field and has been actively studied for decades. An accurate crop cover classification prediction is essential to many downstream research that requires field-level crop cover type, including field-level crop yield prediction. As the crop growing season progresses, crop cover classification results become more and more reliable since the distinguishable signals among different crops have been available in satellite observations. However, late season prediction cannot satisfy most practical usages and there is a great need for accurate real-time crop cover classification. Real-time crop cover classification is to continually generate more and more accurate crop cover classification results as the growing season proceeds. An effective real-time crop cover classification algorithm is the prerequisite of the real-time crop yield prediction. The latter is extremely important to global food production, food security and policy making. How to accurately classify crop covers in a real-time manner has been a research challenge because of the lack of informative satellite information in the early growing season. Although United States Department of Agriculture (USDA) traditionally releases the Cropland Data Layer (CDL) that contains the land cover for the whole United States, it is not available until the spring of the subsequent year, a huge delay comparing with the previous year's harvest time.

Machine learning has been demonstrated to be powerful in many fields and has experienced rapid growth over the past two decades. Generally, a machine learning task can be supervised (labels required), unsupervised (No labels required), or weakly-supervised (a small number of labels required). A machine learning problem can be either classification (to predict categorical memberships) or regression (to predict numerical values). There are existing works that explore machine learning approaches to solve the real-time crop cover classification problems. Existing approaches are centering around using satellite optical data. High resolution satellite optical data facilitates pixel-level and thus field-level prediction of crop covers. Traditional machine learning models including Logistic Regression (LR), Decision Trees (DT), Random Forest (RF), or Support Vector Machines (SVM) have been practiced to process multi-temporal satellite data to classify the crop cover. Recent development of deep learning, a subset of machine learning, offers new approaches to the problems. MultiLayer Perceptrons (MLP), a type of Artificial Neural Network (ANN) is employed to take in satellite spatial and temporal information to classify the corn and soybean. Nevertheless, all above models are not originally designed to handle the sequential data and thus the sequential relations in the time series are not fully interpreted. Some feature engineering works have been practiced to improve the model performance, including extracting vegetation indices (VI), feeding combinations of spectral bands and VI. Recently, Long Short Term Memory (LSTM) and transformer have been incorporated to handle the multi-temporal data. Transformer is more computationally expensive to train compared with LSTM and not necessarily yields better results in crop cover classification due to relatively simple temporal dependencies compared with NLP tasks. However, the real-time performance is still not satisfactory, especially in the early growing season (before July). This is a common failure for all existing methods that merely use satellite information for real-time crop cover classification, and it is caused by lacking informative satellite scenes that can be used to effectively distinguish crops in the early growing season.

3.3 National Planting Acreage Prediction

The United States is the world's largest producer and exporter of corn and soybeans. National-scale crop planted acreage, especially corn and soybeans, plays a significant role in affecting marketing price of corn and soybean and even affecting global food production. Random Forest has been used to predict national-scale soybean area estimation in the United States. Soybean planted region in the U.S. is divided into 20 km*20 km square blocks. Field survey is conducted in each block to collect labels that are used in training, which requires lots of manual labor. However, no effective real-time national acreage model for both corn and soybean have been developed yet since an accurate real-time crop cover classification model is the prerequisite of the national acreage model.

3.4 Goal of Present Disclosure and Potential Contribution

The goal of this section is to develop a new method that can conduct large-scale pixel-level and field-level crop cover type classification in real-time across the year and also predict national-scale crop planted acreage by aggregating the field-scale prediction. Specifically, the process incorporates both historical crop planting patterns and satellite optical data to train the deep learning-based model, BlueBird, that accurately classifies crop cover types in real-time at the national scale. The process performs unprecedented comprehensive leave-one-year-out validations on the whole U.S. corn belt from 2014 to 2019 to demonstrate the model effectiveness and scalability. Through quantitative assessments, it has been shown that BlueBird is able to generate highly accurate crop cover predictions across the year, with high F1 scores compared to the ground truth data. Besides, a real-time national acreage model for corn and soybean is proposed based on BlueBird's real-time prediction. Leave-one-year-out validations on the national acreage model shows the effectiveness in predicting national acreages of corn and soybean in real-time.

The contributions are summarized as follows: 1. An innovative and highly effective method for crop cover classification in the real-time that incorporates both historical planting patterns and satellite optical images has been developed. 2. The algorithm has been scaled up for national field-scale crop cover classification at low cost but high efficiency, which is critical to field-level precision agriculture, early warning of food insecurity, and economic market. 3. It has been proposed to have an effective national acreage model to predict corn and soybean planting size on the national-scale.

3.5 Data

3.5.1 Study Area

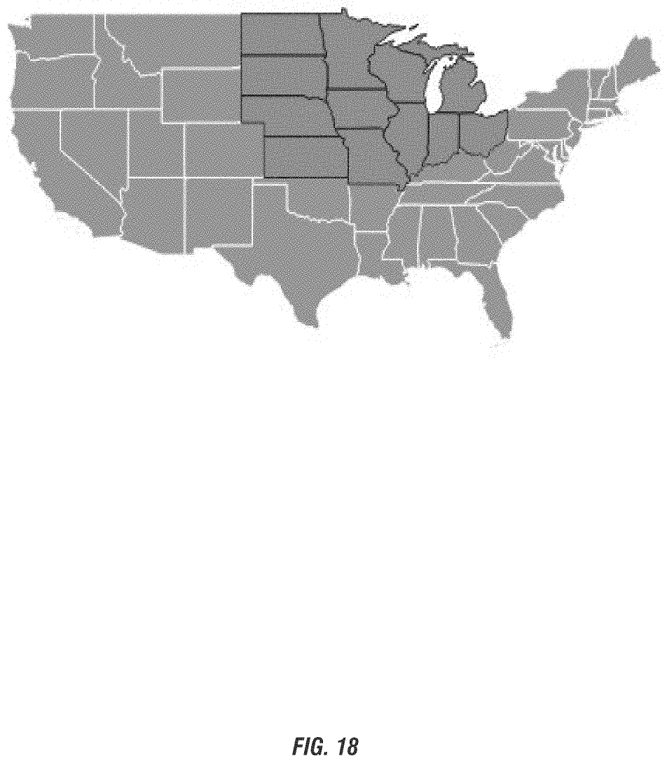

The U.S. Corn Belt (FIG. 18) includes Illinois, Indiana, Iowa, Kansas, Michigan, Minnesota, Missouri, Nebraska, North Dakota, Ohio, South Dakota, and Wisconsin, total twelve states (some versions also contain Kentucky), where corn and soybean are two dominating crop types. Other common crop types/practices include winter wheat, alfalfa and double crops, etc.

3.5.2 Multi-Sensor Data Fusion

Satellite surface reflectance data with a high spatial resolution and high temporal revisit frequency have been desired and demanded by scientific research and societal applications. However, there is always a tradeoff between spatial resolution and temporal frequency for standard satellite missions. Moderate Resolution Imaging Spectroradiometer (MODIS) has medium spatial resolutions of 250 m or 500 m. The coarse resolution precludes the possibility to directly use MODIS for field-level crop cover predictions. However, MODIS are viewing the entire Earth's surface every 1 to 2 days, a high temporal frequency compared with high resolution satellite missions like Landsat. Landsat is a ˜30 meter resolution satellite mission. Currently, there are two Landsat instruments in service (i.e., Landsat-7 ETM+, Landsat-8 OLI). Each Landsat instrument has a revisiting cycle of ˜16 days, a low temporal frequency compared with 1-2 days revisiting cycle of MODIS. Besides, Cloud contamination and the satellite mechanical issue of Landsat 7 further reduce the number of usable pixels. Landsat's low temporal frequency makes real-time crop cover prediction even more difficult since the long-awaited satellite scenes with distinguishable crop signals at the peak of the growing season are highly likely to be contaminated. Without daily high resolution satellite imagery, the real-time crop cover model is not able to produce daily and timely updates.

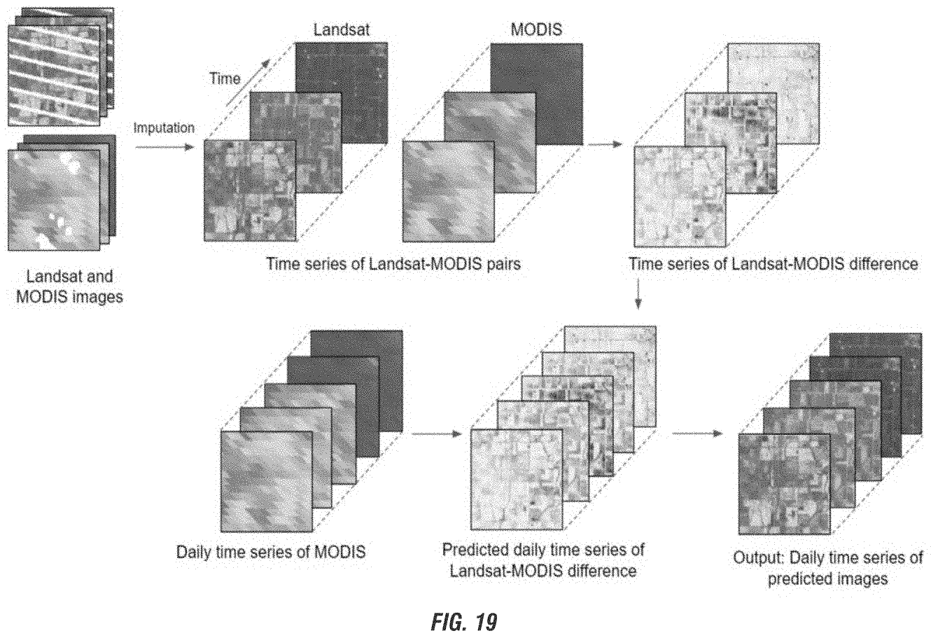

Therefore, aspects of the invention take advantage of the STAIR algorithm (FIG. 19), a fully-automated method to fuse multiple sources of optical satellite data to generate a high-resolution, daily and cloud-/gap-free surface reflectance product. Specifically, aspects of the disclosure fuse Landsat data (˜30 m, ˜16 days) that has high spatial resolution but low temporal frequency with MODIS data (˜500 m, 1 day) that has coarse spatial resolution but high temporal frequency to generate daily, cloud-free, 30 m resolution satellite imagery. STAIR first imputes the missing pixels in satellite images using an adaptive-average correction process, which takes into account different land covers and neighborhood information of miss-value pixels through an automatic segmentation process. After filling the missing pixels, a local interpolation model is employed to predict the Landsat-MODIS difference at a daily level based on available spatial information provided by the Landsat. To obtain the final prediction of the fine-resolution image, the input daily time series of MODIS data is used to further correct the spatial information encoded in the interpolated time series. In this study, we use STAIR data as the satellite optical input.

3.5.3 Cropland Data Layer

Cropland Data Layer (CDL) is the land cover map (˜30 m) of the United States produced by The National Agricultural Statistics Service (NASS) of the US Department of Agriculture (USDA). The model used to produce CDL is trained on labels collected by local FSA offices from farmers and these labels are not publicly available. CDL maps prior to 2008 are usually incomplete and noisy but maps after 2008 are in good quality. The producer accuracy and user accuracy of two major crop types (corn, soybean) are usually above 95%. CDL data of the year will not be available until the spring of the subsequent year and thus motivate the development of real-time crop classification models. Aspects of the present disclosure use CDL data as the ground truth to conduct supervised training on our models.

3.5.4 Common Land Unit

A Common Land Unit (CLU) is the smallest unit of land that has an immutable, contiguous boundary. The boundaries of CLU fields are delineated from permanent features such as roads, rivers. Aspects of the disclosure use the CLU field boundaries to select the fields with more than 80% pixels being the same crop type and use them to randomly sample pixels to form the training data. This extra step aims to extract reliable training samples from CDL that is potentially noisy. CLU can also be used to aggregate pixel-level prediction to field-level. However, since the fields in CLU are usually oversized compared with real farmland fields, the field-level aggregation may drop the accuracy.

3.5.5 Crop Production Annual Summary

NASS releases the crop production annual summary that contains the final acreage of crops in January. Although NASS usually releases a few more reports prior to the crop production summary, including prospective planting reports in March, and crop production reports every month after March, the acreage numbers in those reports are highly likely to change, especially in years when abnormal weather strikes (e.g., historic flooding and precipitation in 2019). Therefore, aspects of the disclosure use the number appearing in the crop production annual summary as the ground truth to evaluate the national acreage model.

3.6 Methods

3.6.1 Model Design Overview

According to aspects of the disclosure, BlueBird is disclosed, which is a deep-learning-based method to accurately classify crop cover types in real-time at the national scale. BlueBird takes crop planting history, specifically types of crops planted in past years, and high-resolution satellite time series taken during the current growing season as inputs. The model integrates historical crop planting information with spatial and temporal patterns discovered from satellite time series to generate accurate and timely crop cover prediction.

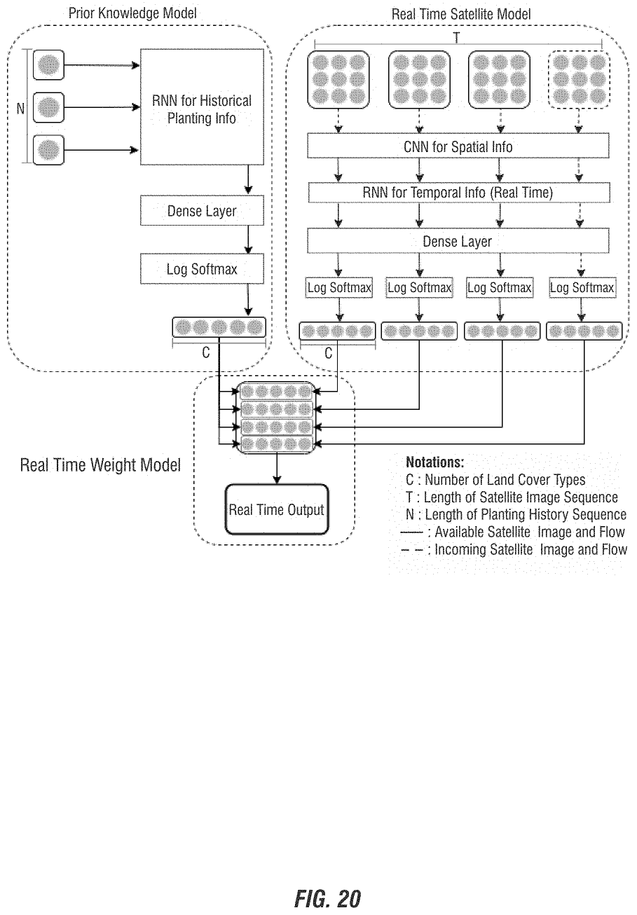

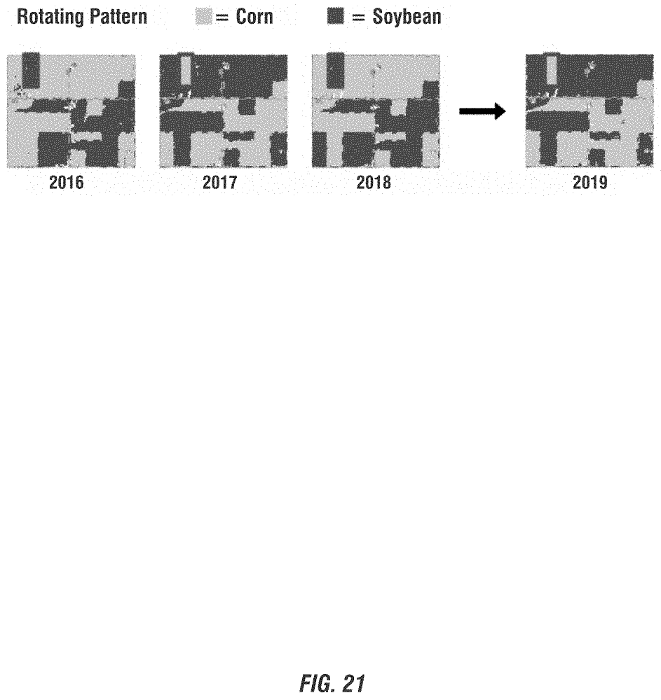

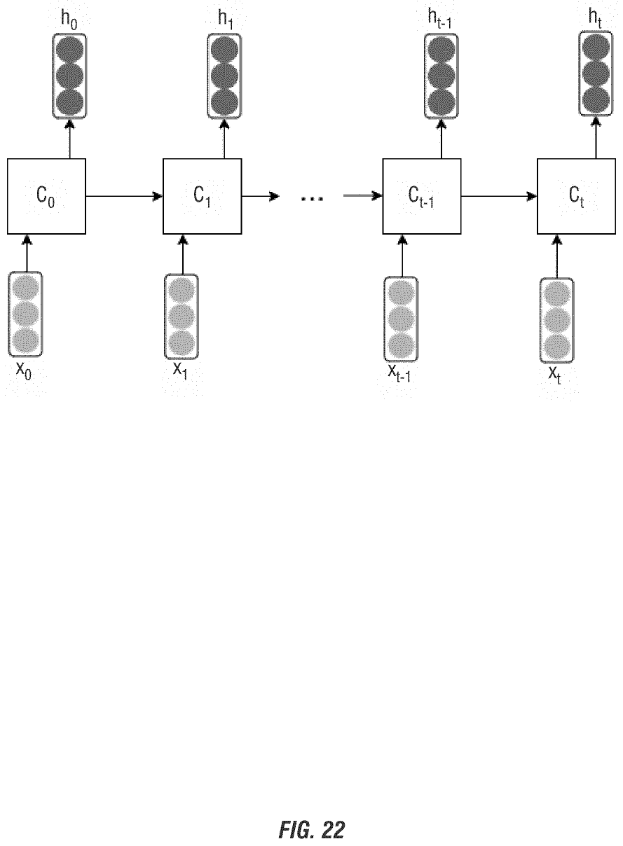

BlueBird consists of three sub-models: prior-knowledge model, real-time optical model, and real-time weight model (FIG. 20). These models are trained separately. Pixel-level planting history serves as the input of the prior-knowledge model, making predictions based merely on the crop rotation practices (for example, loosely one season of soybeans followed by two seasons of corn). The real-time satellite model takes satellite time series data and makes its best-effort prediction based on the optical observations available so far in the current season. The real-time weight model combines the outputs of the prior knowledge model and real-time optical model using a trainable weight matrix that evolves over time, thereby allowing the satellite-based model to be increasingly dominant as more observation data are available. With this setting, the model is able to perform well with insufficient optical observations and further improves the accuracy as the growing season progresses.

Aspects of the disclosure denote the length of whole growing season as T; the length of historical crop type sequence, equivalently the number of years in the past to consider, as N; and the number of target output types as C.

3.6.2 Models

Model 1: Prior-knowledge Model based on Historical Pattern

Crops generally display the most distinguishing characteristics in their optical spectra during the peak of the growing season. For example, the most major crops (corn and soybean) in the US Midwest reach their growing peaks in July and August. Satellite observations during this period, as a result, are extremely valuable features. However, the distinguishing signals are much less significant in the earlier stages of the growing season. Therefore, effective prediction of crop cover in early stages of the growing season is rather difficult if we merely consider remote sensing signals. Furthermore, the latency of high resolution satellite data makes timely predictions even more difficult. Aspects of the disclosure propose to utilize historical crop planting patterns to improve model performance, especially in the early growing season.

Historical crop planting pattern is the sequence of crop types that have been planted in a target pixel in the past years. The rationale behind this approach is that farmers tend to maintain some planting patterns that can potentially increase crop yields and profits. For example, corn-soybean rotation (FIG. 21), the most common pattern in the U.S. Corn Belt, can help effectively control diseases and pests as well as maintain soil health. A planting sequence may show a high prior probability for a specific crop type since the soil is suitable to that crop type. Additionally, unlike current-season satellite observation, planting pattern information is available before the start of the growing season. Therefore, it can provide the model with effective signals to elevate the performance, especially in the early stage.

Aspects of the disclosure use a deep-learning-based model to discover the historical planting pattern. More specifically, we employ Long Short Term Memory (LSTM), a classical type of Recurrent Neural Network, to process the planting sequence of length N. Each LSTM cell has an input gate, an output gate, a forget gate, a cell state and a hidden state. Cell state is used to memorize information over arbitrary time intervals, and the model will gain more learning capacity by increasing the size of cell state. Hidden state is the output of a LSTM cell. Other gates control the flow of information into and out of the cell. Multiple LSTM layers can be stacked to increase learning capacity and capture more complicated temporal features. Aspects of the disclosure use the last hidden state of LSTM as the input to the dense layer since ideally the last output leverages the whole input sequence. The size of LSTM is N, the length of historical crop types.

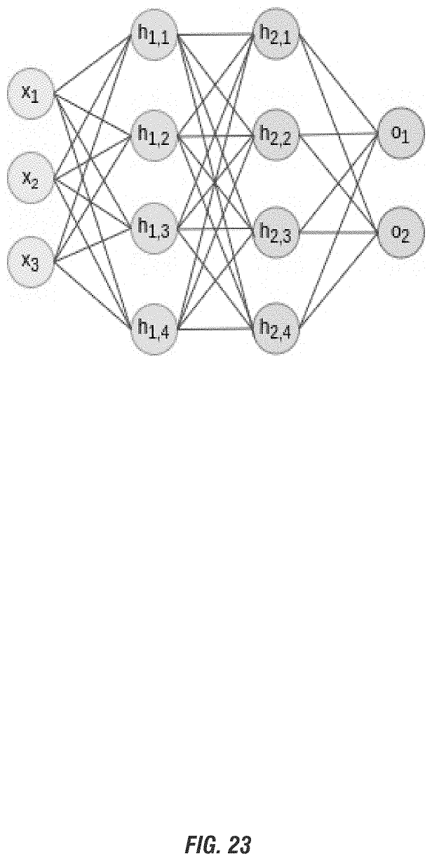

A dense layer (FIG. 23) is also known as a fully-connected layer, consisting of multiple layers of neurons with individual weights. Neurons are interconnected between layers. There is an input layer that has the same number of neurons with input dimension, an output layer that has the same number of neurons with output dimension and zero or multiple hidden layers. Activation function is usually applied between two layers to introduce nonlinearity and speed up training. In our model, we use ReLU (rectifier) as the activation function which is effective in preventing the vanishing gradient problem especially in a very deep network. The operation between each layer is:

h^{L}=σ(W^{T}h^{L-1}+b

σ(a)=max(0,a)

where σ is the ReLU activation function; h\hat{ }L is the output of L's layer; W is the weight;

b is the bias. The input of the dense layer is the last hidden state of LSTM and the output is the probability of each class.

Finally, aspects of the disclosure apply log-softmax to the output of the dense layer as normalization:

$$Log Soft max ( {x}_{i} ) = log ( \frac{exp ( {x}_{i} )}{{\sum }_{j} exp ( {x}_{j} )} )$$

where x_is the output vector; x_iis the output of a target class. Given that the dataset is usually significantly unbalanced, aspects of the disclosure use weighted cross-entropy loss to improve the accuracy of classes with less samples. Aspects of the disclosure use the Adam optimizer to train the prior-knowledge network with back-propagation.

Model 2: Real-Time Optical Model Based on Satellite Data

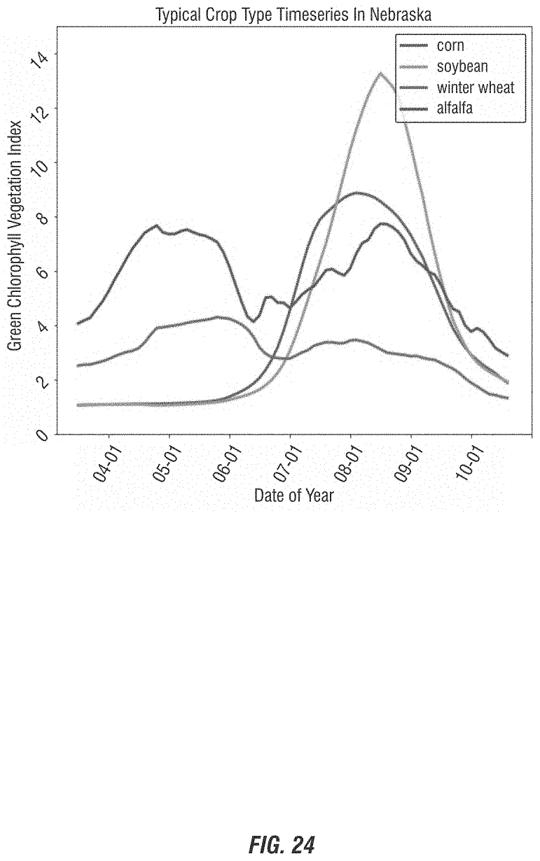

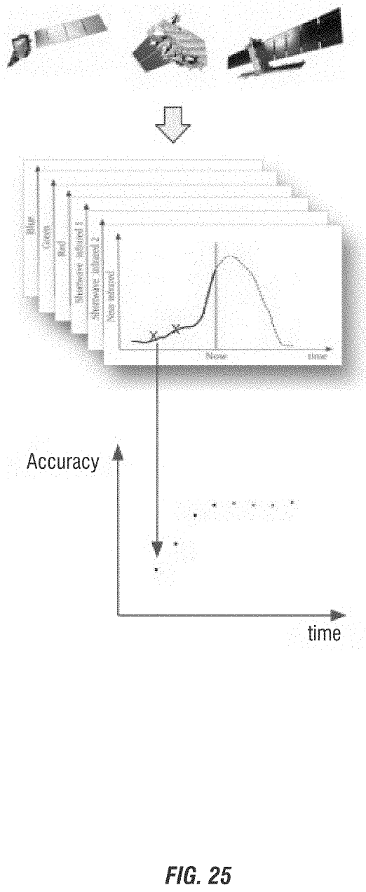

Satellite optical data can capture crop signals that can be used to distinguish different crop types. FIG. 24 shows the Green Chlorophyll Vegetation Index (GCVI) time series of four major crop types planted in Nebraska; corn, soybean, winter wheat, alfalfa. Aspects of the disclosure can clearly show the different temporal patterns among crop types. However, corn and soybeans have similar time series till the mid-June and thus classification using merely satellite optical signals has a low accuracy at that time. After mid-June, satellite missions start to observe distinguishing optical signals with a great latency. Fortunately, the STAIR algorithm provides the generation of daily high resolution images that can be used to update model prediction immediately. The real-time optical model is built in a way that utilizes the daily continuous STAIR data to generate daily crop cover prediction without retraining the model (FIG. 25).

The input of the real-time optical model is an image time series of dimension k*k*c*t, where k is the window size that is used to sample an image around the target pixel; c is the number of optical bands; t is the length of time series. During the training, t is equal to T since the complete time series of the growing season is used. However, in terms of prediction, T is the number of currently available satellite observations. A convolution layer is applied to extract the spatial pattern as well as denoise the optical data:

Y_{i,j}=Σ_{m=∞}^{∞}Σ_{n=∞}^{∞}K_{m,n}*X_{i-m,j-n}

where K is the kernel, as known as the filter; Xis the input image. Real-time functionality is achieved by training LSTM with aggregated loss design. After convolution, the resulting time series is passed to LSTM to extract temporal information. Instead of merely using the last hidden state, which represents the end of season prediction, aspects of the disclosure and model pass all the hidden states to the same dense layer to generate Toutput vectors representing daily real-time predictions in the growing season. For example, h_t is passed to the dense layer to generate the prediction t days after the growing season starting date while h_T is used for the end of season prediction. A total of Tcross-entropy losses are calculated from output vectors (one for each time step). The losses are aggregated and used in back-propagation:

$$Loss = \frac{1}{T} {\sum }_{t = 1}^{T} \\ ρ ( {y}_{t} , Y )$$

where Y is the label; y_t is the generated output by using hidden state of time t; p is the weighted cross-entropy loss function. Given that cell states are able to memorize information in the previous time steps, the hidden states of LSTM should be positively correlated. Losses calculated from Toutput vectors are also positively correlated since all hidden states pass through the same dense layer. Therefore, aggregated loss does not confuse the training but makes the training more stable by taking the average of losses. It explicitly allows the model to improve the prediction of all time steps while maintaining temporal consistency in predictions.

Similarly, aspects of the disclosure apply log-softmax to the outputs and pass them to the real-time weight model. Aspects of the disclosure use the Adam optimizer to train the real-time optical model with back-propagation.

Model 3: Real-Time Weight Model

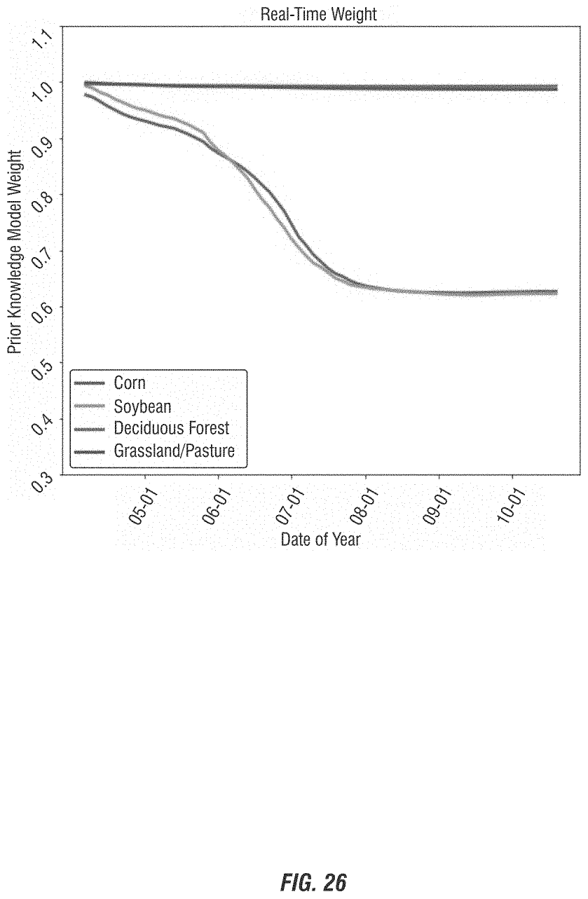

The outputs of prior-knowledge model and real-time optical model are combined using a trainable weight matrix. Weight matrix A of prior-knowledge model has dimension of C*T, where C is the number of classes to classify and Tis the length of the whole growing seasons. The weight matrix of the real-time optical model is defined as 1−W. The rationale behind this setting is that the real-time optical model based on satellite data will be increasingly dominant as more observation data are available while the weight of the prior-knowledge model will decrease. Each land cover type has a unique weight vector of length T. For example, FIG. 26 shows the weight curve of the prior-knowledge model for four major land cover types in Champaign county, Illinois. Among four types, forest and grassland tend to have consistently dominating weight on the prior-knowledge output because it is unlikely for a field to change from those two types to other types. Therefore, the classification of forest and grassland mostly follows historical planting patterns. However, the weights of corn and soybean have a significant drop between June and July because the number of distinguishing satellite images gradually increases.

The real-time weight model takes the log-softmax outputs from the prior-knowledge model and the real-time optical model as the input. During the training, the real-time satellite model produces a total number of Tpredictions while the prior-knowledge model only has one prediction that is used for all time steps. Output from two sides are weighted using a trainable weight matrix Λ of dimension C*T:

y_t=Λt*p±(1−Λ_t)*s_t

where Λ is the weight matrix of the prior-knowledge model; p is the log-softmax output of the prior-knowledge model; s_t is the log-softmax output of the real-time optical model at time step t; y_t is the output of the real-time weight model at time step t. Aspects of the disclosure still use the aggregated loss to training the weight matrix with regularization that ensure the weights of the prior-knowledge model never increase compared with the previous timestep:

$$Loss = \frac{1}{T} {\sum }_{t = 1}^{T} \\ ρ ( {y}_{t} , Y ) + {\sum }_{t = 1}^{T} \\ max ( {Λ}_{t} - {Λ}_{t - 1} , 0 )$$

where Y is the label; ρ is the weighted cross-entropy loss function. Aspects of the disclosure use the Adam optimizer to train the real-time weight model with back-propagation. Output of the real-time weight model is the final output of BlueBird.

3.7 National Planted Acreage of Corn and Soybean

The United States is the world's largest producer and exporter of corn and soybeans. Therefore, the size of the two crops in the U.S. plays an important role in determining market price of corn and soybean. United States Department of Agriculture National Agricultural Statistics Service (USDA NASS) provides the potential sources of national corn and soybean acreage every year, including Prospective Plantings, Acreage, and Crop Production report.

A national acreage model of corn and soybean is proposed based on the real-time corn belt prediction of BlueBird. Aspects of the disclosure first generate historical end-of-season crop cover predictions in the past years, and aggregate the predictions to county-level acreages of corn and soybean. Aspects of the disclosure train a linear model for each county to map our end-of-season county-level acreage to the ground truth provided by NASS. The goal of county-level linear models is to correct the bias between CDL acreage and the ground truth acreage since BlueBird is trained on CDL data and its predictions may leverage the bias. After training the county-level model, aspects of the disclosure aggregate the end-of-season county-level acreage to the corn belt acreage and train a linear model between the corn belt acreage and the national acreage.

3.8 Experimental Design

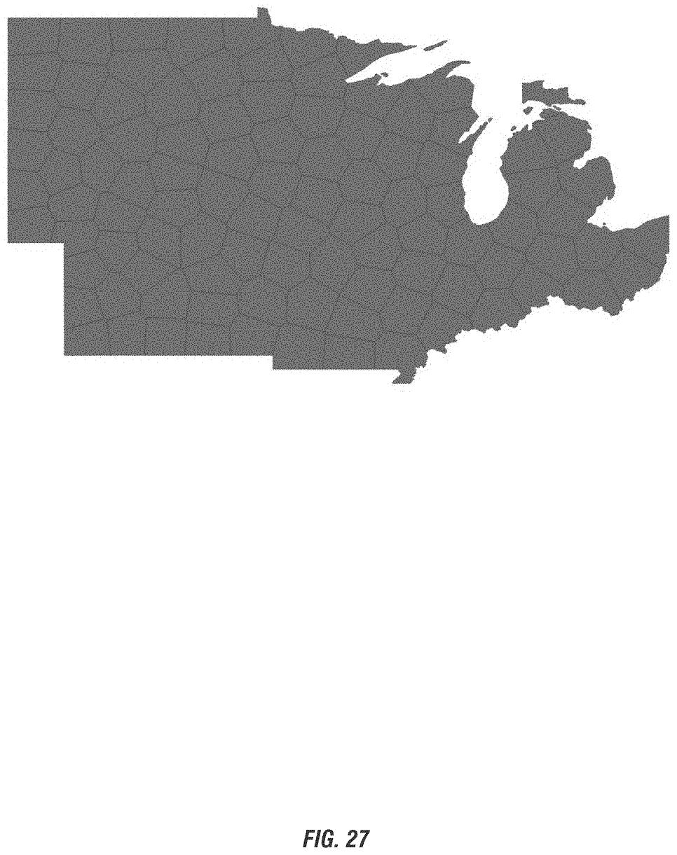

BlueBird is designed to accurately classify crop cover types in real-time at large scale. Aspects of the disclosure conducted experiments in the whole U.S. corn belt from 2014 to 2019 including 12 states to investigate the real-time performance of BlueBird. Since crop growing patterns and farmers' practice may be very different in different regions, aspects of the disclosure divide the whole corn belt into 100 equal-size regions (FIG. 27). Cropland Data Layer is used as the ground truth data to train the models. However, considering that CDL has a certain amount of noise (>5%) that may affect training quality, aspects of the disclosure use field boundaries to select the fields with more than 80% pixels being the same crop type and use them to randomly sample pixels to form the training data. Aspects of the disclosure perform leave-one-year-out cross validation from 2014 to 2019. For example, aspects of the disclosure train the models using the data from 2014 to 2018 and validating using all pixels in the whole corn belt of 2019. Snow may also affect the leave-one-year-out validation results by affecting the quality of satellite time series data. During validation, aspects of the disclosure set the start date of satellite time series to be the date when the snow has melted for all years from 2014 to 2019, to eliminate the noise caused by snow in the satellite sequences. Instead of using daily satellite time series, aspects of the disclosure use a satellite scene every three days to reduce the computational cost while maintaining similar performance. Aspects of the disclosure compare BlueBird's prediction on June 1 and August 30 with CDL, though CDL is not perfectly accurate. The evaluation metric we use to compare BlueBird's predictions with CDL is F1 score that considers both precision and recall:

$$f 1 = \frac{2 * precision * recall}{precision + recall}$$

$$precision = \frac{True Positive}{True Positive + False Positive}$$

$$recall = \frac{True Positive}{True Positive + False Negative}$$

where true positive, true negative, false positive, false negative are numbers appearing in the confusion matrix. F1 is usually more useful than accuracy, especially when the dataset is unbalanced.

National acreage model's evaluation is based on BlueBird's predictions. Aspects of the disclosure use the leave-one-year-out predictions of BlueBird to conduct another leave-one-year-out validation on the national acreage model. Specifically, aspects of the disclosure are interested in the predicted national acreage of corn and soybean. To quantify the real-time performance, aspects of the disclosure compare our national acreage predictions with NASS ground truth on two selected time steps, June 1 and August 30.

3.9 Results

3.9.1 Pixel-Scale Performance: Using Champaign County, IL as an Example

In this section, the real-time performance of BlueBird is evaluated by examining the detailed results of Champaign County, Illinois. Champaign County has a total area of 638,767 acres and is located in the east-central part of Illinois. Corn and soybeans are the major crops accounting for about 92% of the farmland area in Champaign.

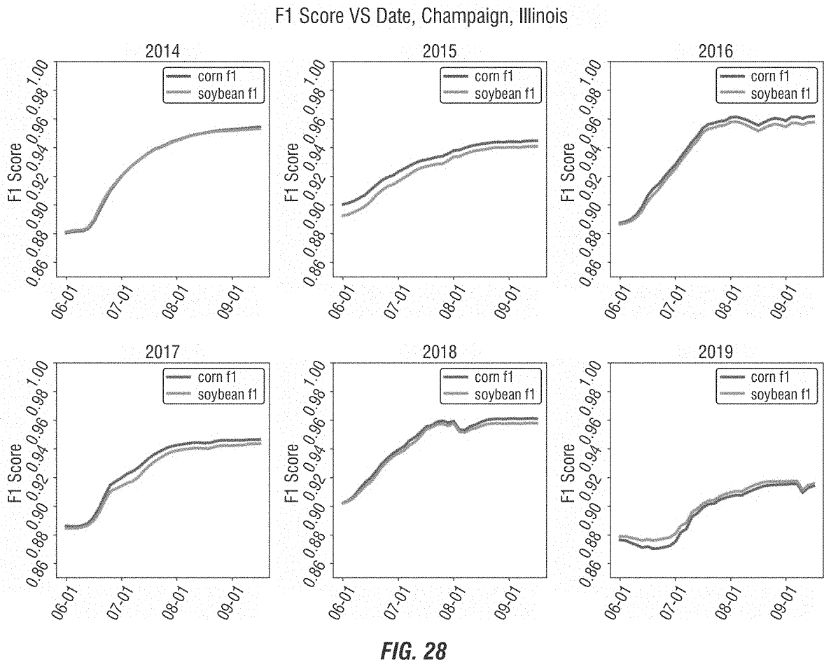

FIG. 28 shows the real-time curve of corn and soybean F1 score calculated with CDL from 2014 to 2019. Aspects of the disclosure can clearly show that incorporating historical planting information, BlueBird achieves a high F1 score (˜0.89) on June 1. Furthermore, the prediction is gradually refined as the growing season processes, using satellite optical images. The best year (2016) among six validation years can reach 0.962 F1 for corn and 0.958 F1 for soybean. The worst year (2019) has a 0.916 F1 for corn and 0.918 F1 for soybean. In 2019, prevented planting and delayed planting happens to many fields across the corn belt because of the historic flooding and precipitation. This special situation leads to the slightly bad result in our leave-one-year-out validation. All other normal years have a F1 somewhere close to 0.95.

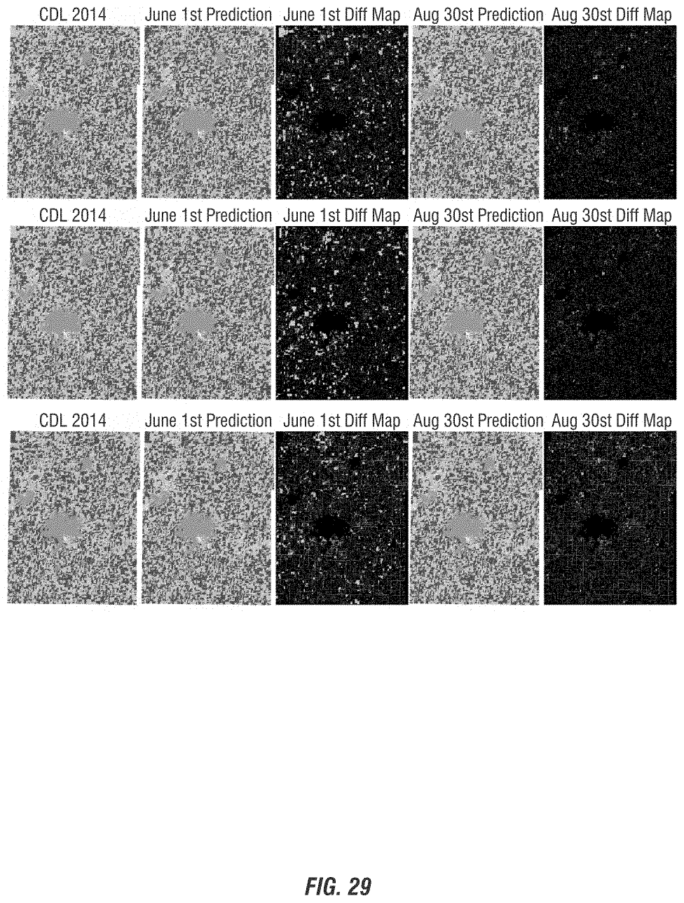

FIG. 29 shows the exact spatial comparison between CDL and BlueBird's predictions (June 1 and August 30) for 2014, 2016 and 2019. The three years are chosen such that they cover the best year, the worst year and a moderate year in terms of F1 scores. The difference map only shows the inconsistency between BlueBird's prediction and CDL in cropland. Considering the fact that CDL contains some noise, the prediction of June 1st already looks quite promising. It is also shown that the significant drop in the number of incorrect classified pixels from June 1 to August 30, which shows the further improvement of predictions. Most incorrect pixels happening in August 30's predictions are discontinued pixels which are likely to be caused by the noise in the CDL.

3.9.2 County-Scale Performance Across the Midwest

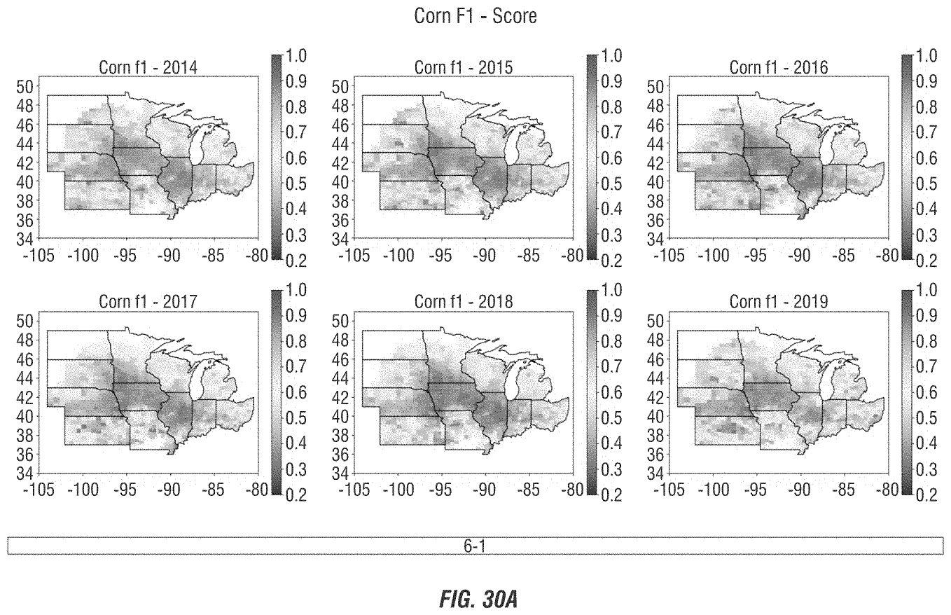

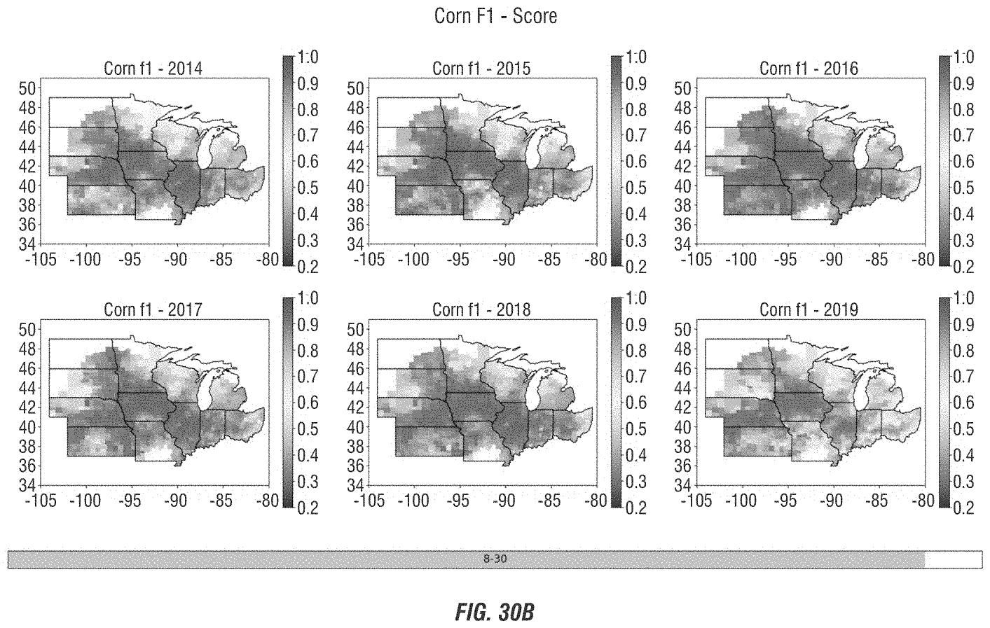

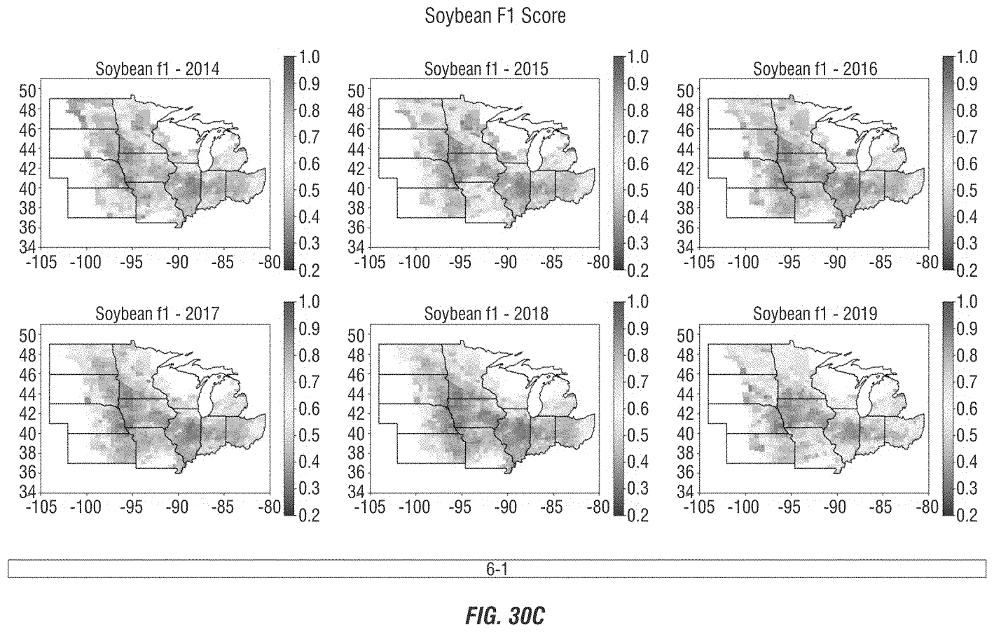

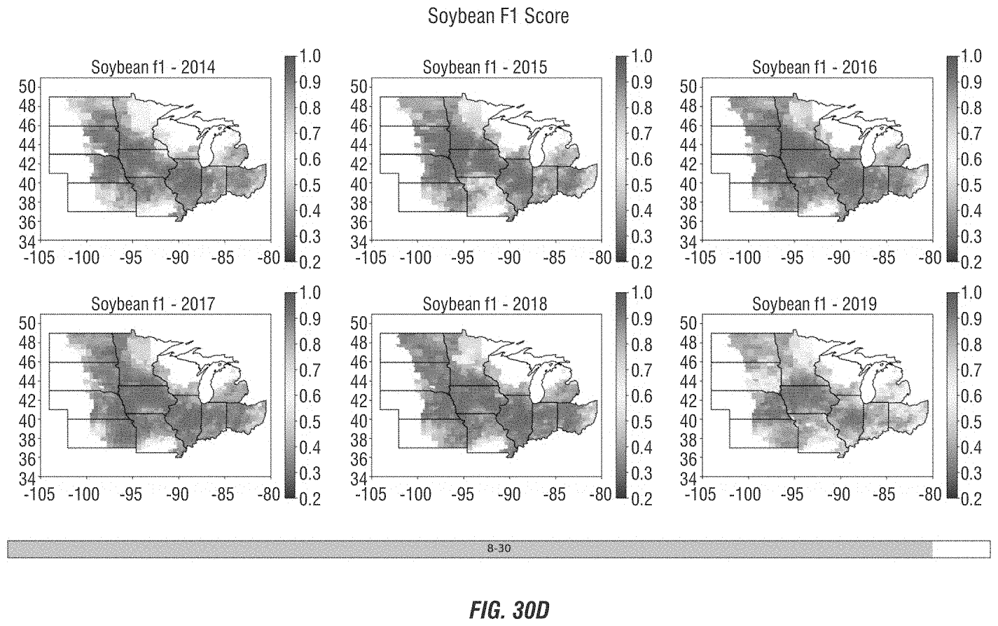

Aspects of the disclosure finish comprehensive validation across the whole Midwest including Illinois, Indiana, Iowa, Kansas, Michigan, Minnesota, Missouri, Nebraska, North Dakota, Ohio, South Dakota, Wisconsin. After generating the leave-one-year-out validations for the whole U.S. corn belt, aspects of the disclosure process the county-level corn and soybean F1 score and visualize the map for the whole U.S. corn belt. FIG. 30 shows the county-scale F1 score for the whole corn belt on June 1 and August 30 for six validation years (counties that barely contain corn or soybean are intentionally left blank in the map). For regions where corn and soybeans cover most of the farmlands, the prior-knowledge model can yield a quite good early-season prediction on June 1. End of season prediction on August 30 reaches the highest classification performance.

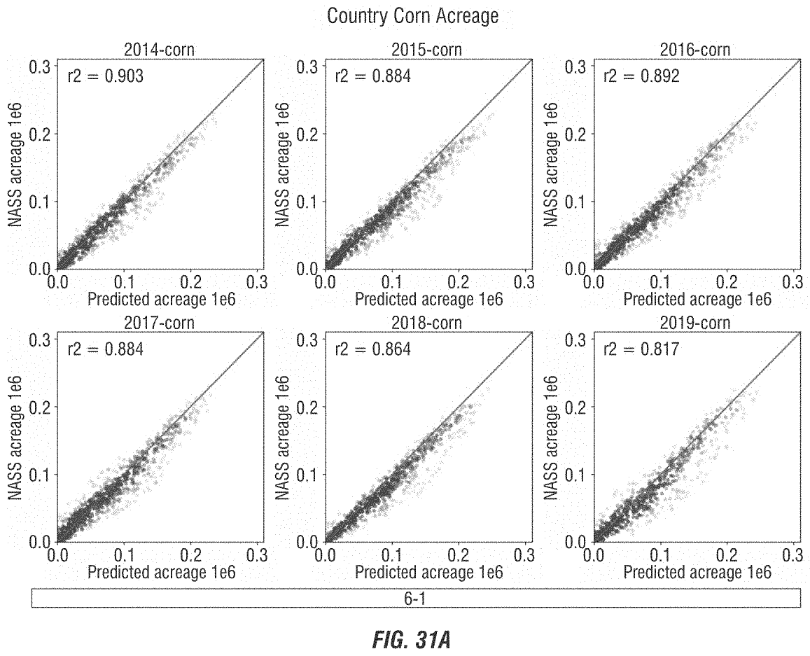

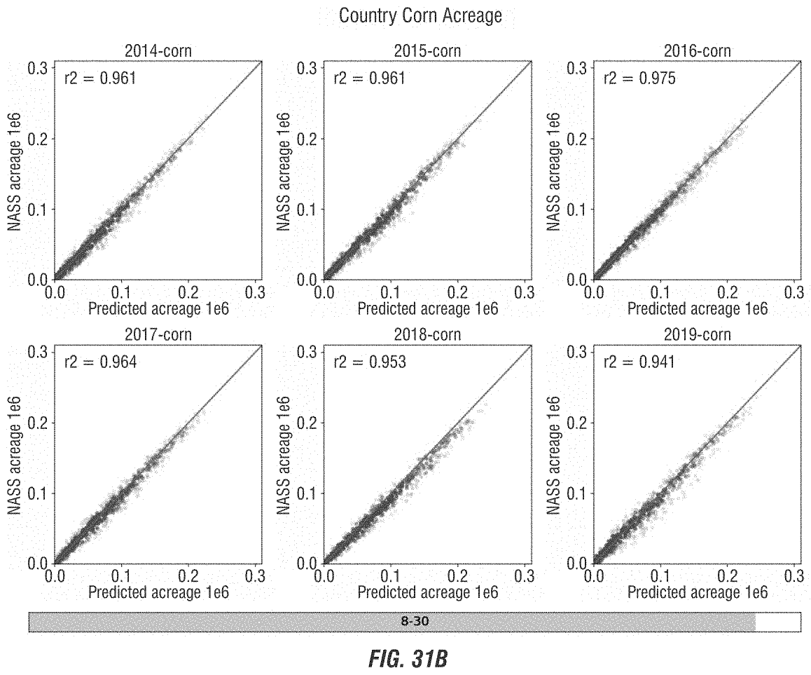

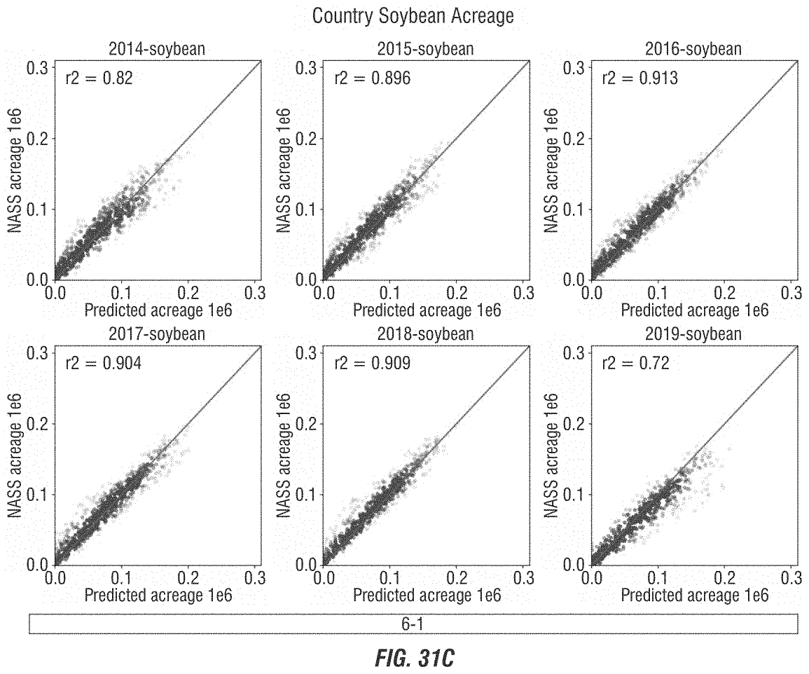

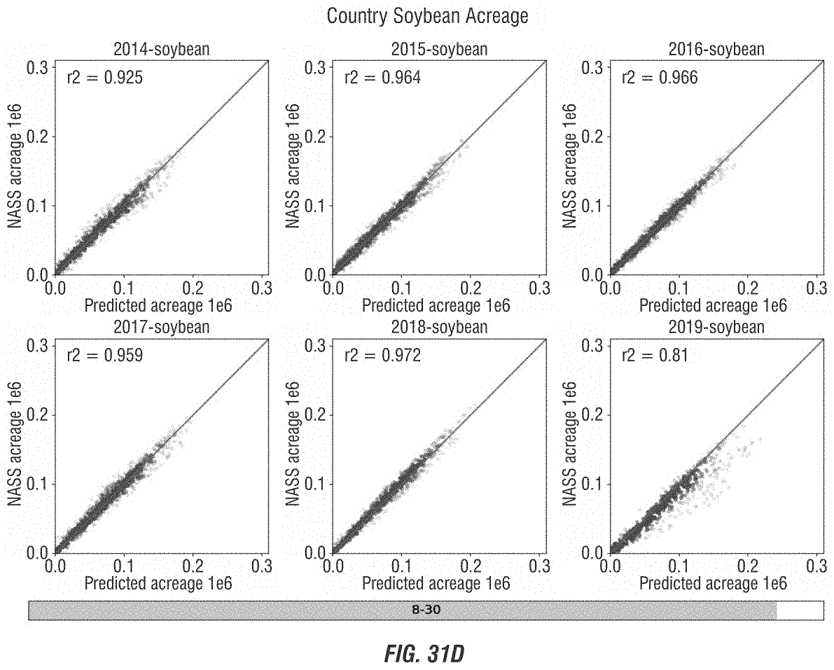

Considering that CDL is not perfectly accurate, aspects of the disclosure compare BlueBird's prediction with NASS's county level acreage ground truth for corn and soybean. By aggregating the BlueBird predictions to county-scale, aspects of the disclosure generate the scatter plot using BlueBird's acreage and county acreage released by NASS. FIG. 31 shows the scatter plots on June 1 and August 30 for six validation years. In early season prediction (June 1), most years have a high r\hat{ }2 close to 0.9. End of season predictions on August 30 further improve the r\hat{ }2 in all the six years. In 2019, historic flood and precipitation caused an unexpectedly large number of prevented planting which seldom happened in previous years. As a result, the leave-one-year-out result for 2019 is relatively bad since there is not enough training data in previous years.

3.9.3 National-Scale Aggregated Performance

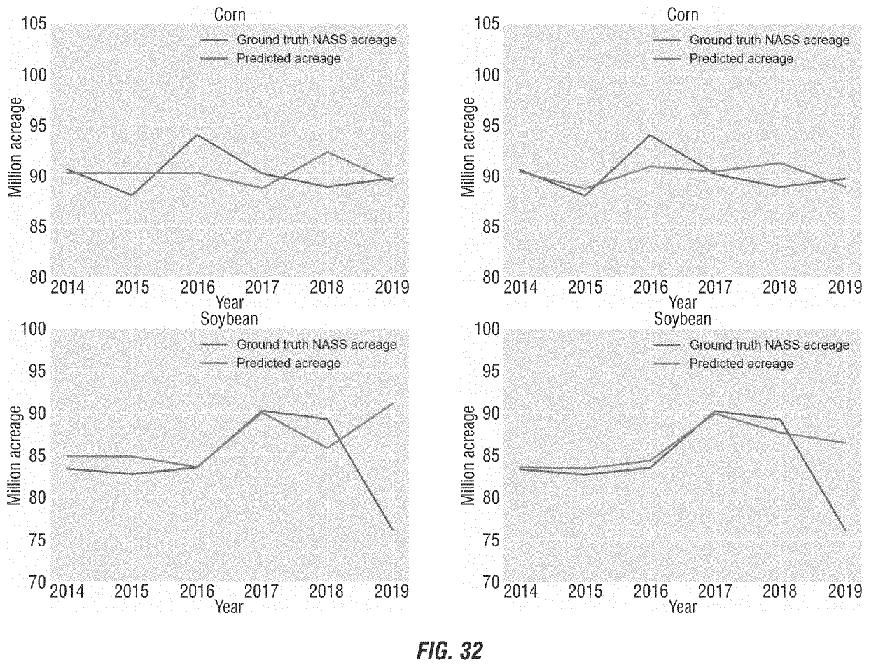

The comparison between the national acreage predictions with NASS nation acreage ground truth on June 1 and August 30 are shown in FIG. 32. Aspects of the disclosure calculate RMSE of the percentage error compared with NASS ground truth for predictions of both dates. Error of Corn acreage has a RMSE of 2.12% on June 1 and a RMSE of 1.36% on August 30. Error of soybean acreage (2014 to 2018) has a RMSE of 1.70% on June 1 and a RMSE of 0.85% on August 30. When calculating soybean acreage's RMSE, aspects of the disclosure leave out the abnormal year of 2019, since its huge error may significantly influence the general evaluation of the acreage model. The national acreage model starts with a promising acreage prediction and improves the prediction as BlueBird gradually refines the classification.

3.10 Discussion

3.10.1 Advantages Over Existing Approach

BlueBird has several advances compared to the existing methods. Firstly, BlueBird achieves better performance than other methods. As the first crop classification model that utilizes historical planting pattern information, BlueBird is able to maintain a high accuracy across the whole year while other approaches fail to effectively predict the crop cover in early growing season. In areas where corn and soybean are dominant, the prior-knowledge model generates predictions with F1 score above 0.85 on June 1 when crops seldom start to grow. Even in the late growing season, the planting pattern information can still contribute to improve model performance because of the real-time weight model.

Secondly, the real-time satellite optical model employs both convolution and recurrent neural networks to automatically leverage both spatial and temporal information from optical data while none of the existing approaches use the setting of ConvLSTM. Besides, BlueBird takes full advantage of LSTM by training with aggregated loss over outputs generated by all time steps. This setting further stabilizes the training process and allows a perfect information inheritance between consecutive LSTM memory cells. Therefore, BlueBird is able to generate real-time predictions across the season without retraining the model or training different models for different dates, a key factor contributing to the scalability of BlueBird.

Thirdly, the present disclosure demonstrates that BlueBird's effectiveness and scalability on the nation-scale by generating leave-one-year-out validations over the whole U.S. corn belt from 2014 to 2019. None of the other works has done similar comprehensive large-scale validations. The disclosure also proposes an effective national acreage model based on BlueBird's large-scale predictions to predict the national acreage of both corn and soybean, which is an important downstream analysis that is not included in other existing works.

3.10.2 Analysis of the Year 2019

Historic flooding and precipitation cause a large amount of prevented planting. The most significant reason leading to relatively compromised model performance is that prevented planting (fallow) seldom happens in the previous years. During the leave-one-year-out validation of 2019, the model is trained using data from 2014 to 2018, which contains few prevented planting samples and thus yield a worse performance than other years.

Another explanation is that there are crop growing signals on fields that are classified as prevented planting. By examining the optical time series, it can be noticed that many pixels that are classified as prevented planting in CDL are actually late-planted with soybean after the disasters. Even if the crops are somehow destroyed by the flooding, a small portion of remaining crops on fields might still grow but not get harvested by farmers and the farmers are likely to report prevented planting for the fields. Besides, aggregated county-level acreage from CDL also shows a general overprediction of soybean acreage, which means that BlueBird will potentially inherit the error in CDL since we use CDL as labels to train the model.

### Example 4: A Method to Predict Crop Sowing/Planting Date from Time Series Remote Sensing Images and Weather/Environmental Information

A purpose of aspects and/or embodiments of the present disclosure is to estimate row crop sowing/planting date using time series of satellite remote sensing data without requesting any information from farmers. It is a new method in terms of considering both satellite and weather/environmental information together to estimate crop sowing/planting date. Previous methods either only use satellite data, or only use weather/environmental data, but no methods consider both satellite data and weather/environmental information to estimate the crop sowing/planting date. The method estimates sowing/planting date at each individual field scale and is scalable for large area applications. Demonstration study has been conducted to estimate sowing/planting date for corn and soybean over the U.S. Midwest, and the results show that the method has the highest performance compared with other approaches.

4.1 Description of the Method

A. Aspects and/or embodiments of the present disclosure use time series of satellite data, weather and other environmental data to estimate sowing/planting date of row crops at a field scale for large areas. Satellite data here could be raw spectral band data, fused spectral band data, or derived vegetation indicators. Weather data here could be any gridded or non-gridded products containing key weather variables, including (but not limited to) air temperature, precipitation, vapor pressure deficit, relative or specific humidity, and soil moisture. Soil data here could be either observed or model-simulated products.

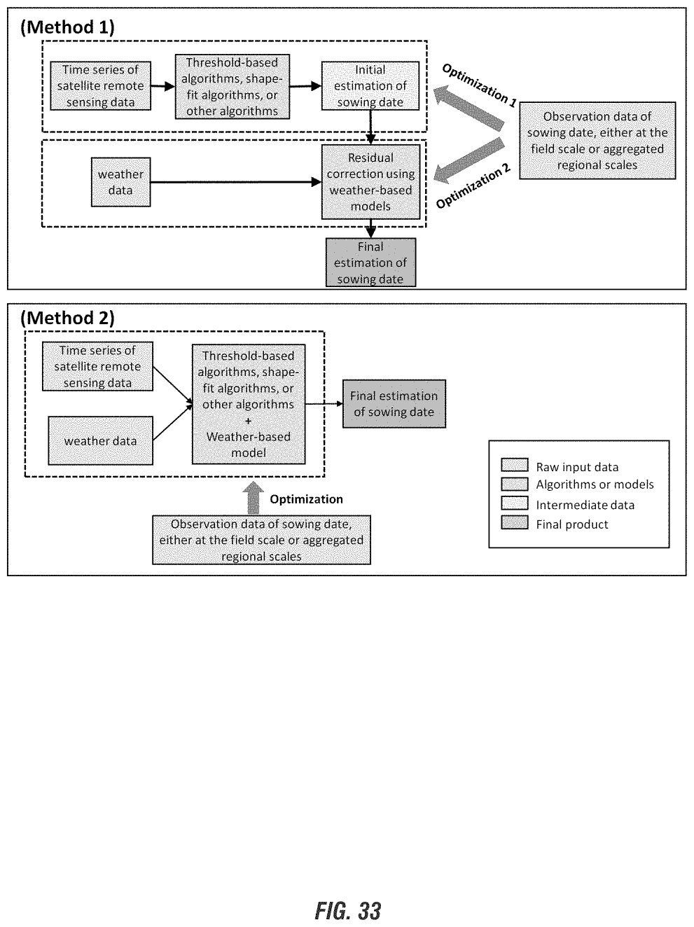

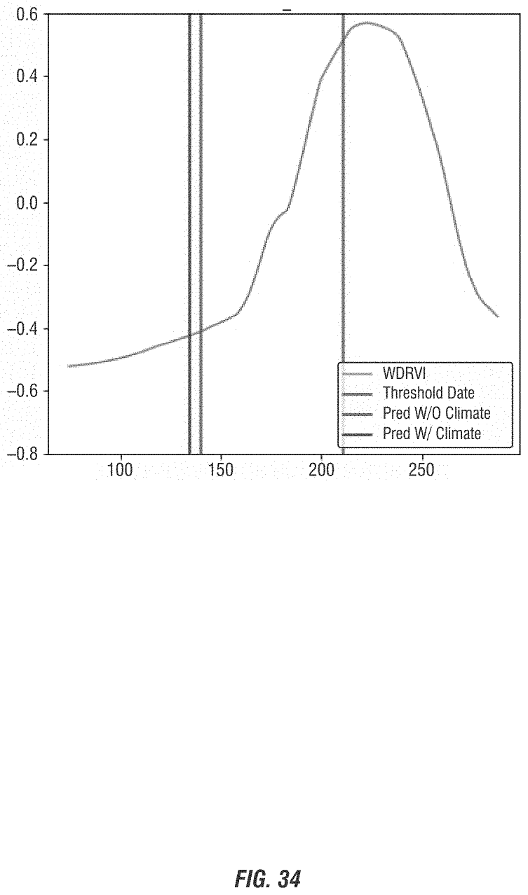

B. Two major steps are employed to make a final estimation of sowing/planting date in our method (Method 1, in FIG. 33). First, based on the time series information and a global rule (there can be a variety of global rules), the method first derives an initial sowing date estimation for each field at a regional scale (e.g., county, or agricultural district). The second step is to adjust the initial estimate based on the weather and other environmental information during the planting periods. For example, we can include weekly information for April and May for the U.S. Corn Belt if we are estimating the sowing date for corn and soybean in this region. The optimization is also done at the regional scales.

C. The above two steps can also be combined to be done in one step by developing a joint function that includes the satellite and weather/environmental information (Method 2, in FIG. 33).

D. The parameter optimization of the (b) or (c) can be done using either field sowing/planting date observation or regional aggregated planting date statistics (e.g., USDA's planting report). The optimized parameters for the model can then be directly applied at the pixel scale or field scale to estimate sowing/planting date at high spatial resolution.

4.2 Demonstration of the Method

It has been demonstrated that the method to estimate sowing/planting date for corn and soybean over the U.S. Midwest. In this specific realization of the method, we used a time series of STAIR MODIS-Landsat fusion data as inputs. The wide dynamic range vegetation index was derived from the STAIR fusion surface reflectance data. The method implemented three different rules to get the initial sowing date estimation from the WDRVI time series: (1) Find a threshold date as the first day when the WDRVI curve of crops reaches a certain percentage of the total WDRVI growth during the growing season, and then fit a county-specific parameter that counts backward from the threshold date; (2) Find a threshold date as the first day when the WDRVI curve of crops has reached a certain amount of growth from the pre-season value, and then fit a county-specific parameter that counts backward from the threshold date; (3) Fit the field-level WDRVI series towards smoothed series from two test sites, and then project the planting dates of the test sites with the fitted parameters. In the first two rules, the county-specific backward counting parameters were optimized by minimizing the KL divergence between the predicted sowing date distribution and the ground truth sowing date distribution at the county level. Finally, a linear model that takes an input vector of county-level precipitation, soil moisture and temperature is used to correct the residual error in the initial estimations. The linear model is fine-tuned by minimizing the KL divergence between the predicted sowing date distribution and the ground truth sowing date distribution of all the counties within Illinois, Indiana, and Iowa.

The aspects and/or embodiments of the disclosure combined the first and second rules to get the best solution. We first determined the series base value for each county by taking the lower 5th percentile of the smoothed county-level series, and averaged over all years. We find that the value 0.75 acts as a good candidate threshold for the amount of growth in the second rule, counting from the pre-season base value. If, for some reason, even the peak of the series is below this threshold, we fall back to the first rule, and choose 75% as the expected percentage of growth.

To get coarse sowing date prediction, a backward counting or shift parameter (county_shift) needs to be subtracted from the threshold date (td). Each county has a different shift parameter. For years from 2000 to 2012, we used the ground truth data from Lobell et al. (2014) to generate a separate ground truth distribution for each county. We also generated a separate prediction distribution for each county, using (td-county_shift) as field-level predictions. Then the county-level KL divergence cost can be defined as:

$${\sum }_{x ∈ X} P ( x ) log ( \frac{P ( x )}{Q ( x )} )$$

where P(x) is the ground-truth distribution, Q(x) is the prediction distribution, and are the (discretized) bins. We set the bin range to (90, 160) for corn and (110, 180) for soybean, which is derived from ground truth data. The bin increment is 5 days. For other selected years (2013-2019) in the selected states, we utilized the aggregated district-level crop progress reports from USDA to generate ground-truth distributions for each year. We used the bin range and bin increment of the reports to generate prediction distributions for each year. This gave us another KL divergence cost, but on the district level. For those groups of counties with crop progress reports, the district level KL costs for each year are added to the county level KL costs for each county, and the shift parameters of all those counties are jointly optimized. For counties without crop progress reports, the county level KL costs were optimized individually.

We then fine tuned the predictions using county level climate/soil moisture data. The climate data used here was from PRISM and soil moisture data was from NLDAS-Noah. For each county and each year, we extracted a feature vector (feats) that consists of the following features:

1. Mean Temperature of April 1-15;

2. Mean Temperature of April 16-30;

3. Mean Temperature of May 1-15;

4. Mean Temperature of May 16-31;

5. Mean Precipitation of April;

6. Mean Precipitation of May;

7. Mean Soil Moisture of April (0-100 cm);

8. Mean Soil Moisture of May (0-100 cm).

Each feature has a corresponding coefficient. Using the coefficients (coeffs), the predictions within each county can be fined tuned as:

td−county_shift−coeffs·feats˜interp

where interp is an additional intercept fitted to the climate/weather linear model. Unlike the parameter county_shift, which varies spatially, coeffs and interp are shared across all counties in all states. As county_shift is fitted in the previous step, only coeffs and interp needs to be fitted here to help reduce the residual error. We again calculate the per-county KL cost using the ground truth dataset from 2000 to 2012, and district level KL cost using the crop progress reports for other selected years and selected regions. As coeff and interp are global parameters, we simply add up all the individual costs on the county and district levels and feed the final accumulated cost into the optimization routine.

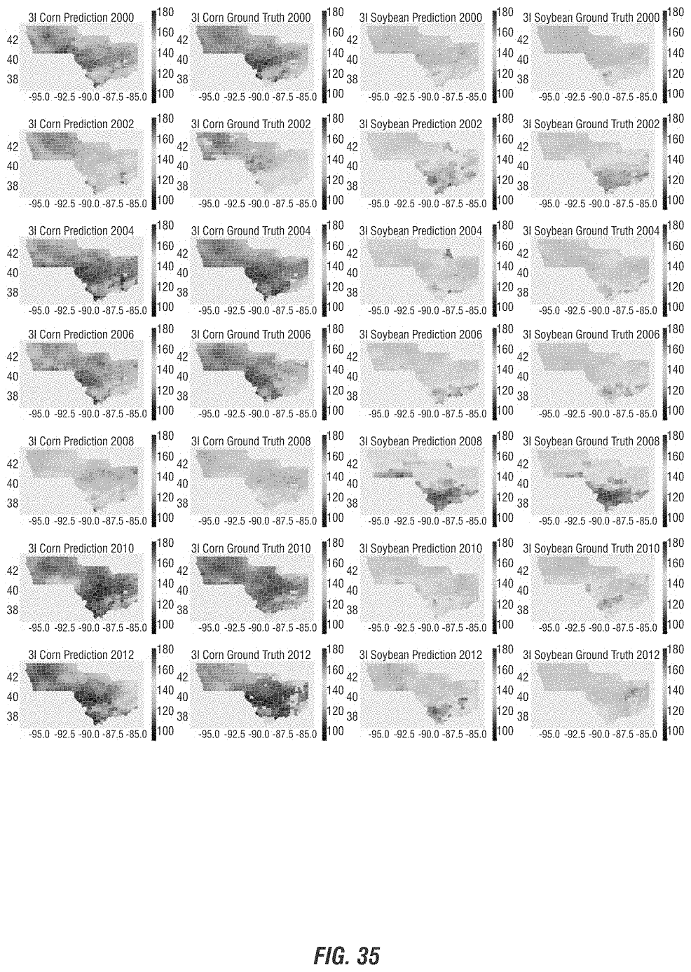

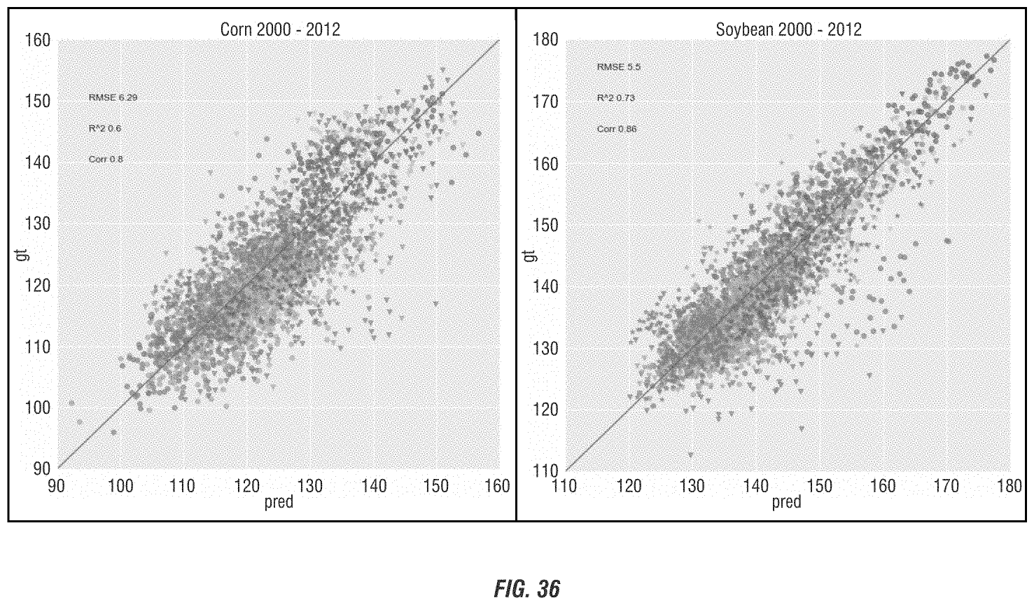

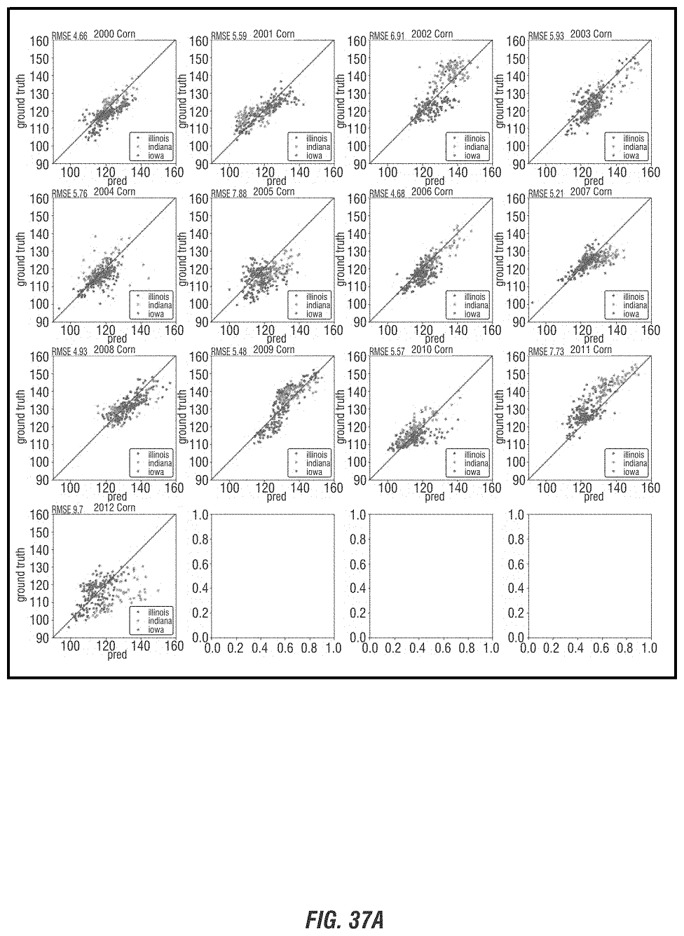

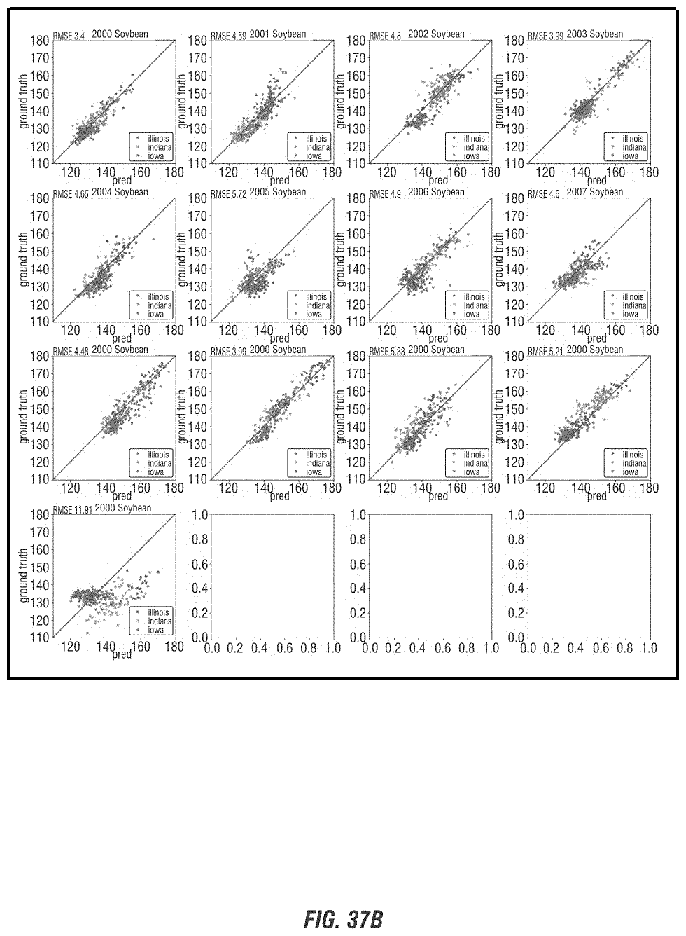

We compared our predictions with benchmarking ground truth data over 3 I-States during 2000 to 2019. The spatial maps and scatter plots are shown in FIGS. 35, 36, and 37A-B, respectively. Overall, our method has good performance in capturing the spatiotemporal variabilities of sowing dates for both corn and soybean, with RMSE of 6.29 and 5.5 days, and R² of 0.6 and 0.73 for corn and soybean, respectively.

Accordingly, the following methods, embodiments, and/or aspects of the disclosure may be included.

A method of predicting key phenology dates of crops for individual field parcels, farms, or parts of a field parcel, in a growing season comprising the following steps:

a. Gathering environmental variables and remotely sensed data in the target growing season.

b. Designing a statistical or machine learning model or explicit algorithms with parameters that predicts the phenology dates from the environmental variables or remotely sensed data.

c. Optimize parameters in the model or algorithm using observation of key phenology dates and the corresponding environmental or remotely sensed data.

The method may also include wherein the statistical or machine learning model or explicit algorithm include the following steps:

a. Generating an initial prediction using either environmental variables alone or remotely sensed data alone.

b. Generating a refined prediction by predicting the errors of the initial prediction using inputs (remotely sensed or environmental) that have not been used in the first step.

The method may also include wherein growing season is {the current ongoing growing season, a past growing season} (maybe expand into separate dependent claims).

The method may also include wherein the explicit algorithm involves calculating thresholds based on descriptors of the geometric shape of time series of remotely sensed or environmental data.

The method may also include wherein the observation of phenology dates comes from survey or otherwise collected ground truth data.

The method may also include wherein the observation of phenology dates comes from predictions of another statistical or machine learning model.

The method may also include wherein the environmental variables include one or more such as: temperature, humidity, precipitation, and/or vapor pressure deficit.

The method may also include wherein the remotely sensed data can be satellite data, satellite-derived indices, airborne remote sensing data, UAV-collected data, data collected by ground vehicles, and/or synthetic data generated from any combination of the aforementioned sources.

Therefore, various aspects and/or embodiments of systems, methods, and/or otherwise have been provided. As noted, the disclosure can utilize many different inputs and also can be utilized using models, such as machine-learning models. The models or any other aspect of the disclosure can include the use of a machine in the form of a computer system within which a set of instructions, when executed, may cause the machine to perform any one or more of the methods discussed above. According to at least some embodiments, the machine may be connected (e.g., using a network) to other machines. In a networked deployment, the machine may operate in the capacity of a server or a client user machine in server-client user network environment, or as a peer machine in a peer-to-peer (or distributed) network environment.

The machine may comprise a server computer, a client user computer, a personal computer (PC), a tablet PC, a smart phone or other handheld, a laptop computer, a desktop computer, a control system, a network router, switch or bridge, or any machine capable of executing a set of instructions (sequential or otherwise) that specify actions to be taken by that machine. It will be understood that a communication device of the subject disclosure includes broadly any electronic device that provides voice, video, or data communication. Further, while a single machine is illustrated, the term “machine” shall also be taken to include any collection of machines that individually or jointly execute a set (or multiple sets) of instructions to perform any one or more of the methods discussed herein.

The computer system may include a processor (e.g., a central processing unit (CPU), a graphics processing unit (GPU, or both), a main memory, and a static memory, which communicate with each other via a bus. The computer system may further include a video display unit (e.g., a user interface with a screen and/or a graphical user interface (GUI)), a flat panel, or a solid-state display. The computer system may also include one or more input devices (e.g., a keyboard), a cursor control device (e.g., a mouse), a disk drive unit, a signal generation device (e.g., a speaker or remote control), and/or a network interface device.

As noted, the computing system will preferably include an intelligent control (i.e., a controller) and components for establishing communications. Examples of such a controller may be processing units alone or other subcomponents of computing devices. The controller can also include other components and can be implemented partially or entirely on a semiconductor (e.g., a field-programmable gate array (“FPGA”)) chip, such as a chip developed through a register transfer level (“RTL”) design process.

A processing unit, also called a processor, is an electronic circuit which performs operations on some external data source, usually memory or some other data stream. Non-limiting examples of processors include a microprocessor, a microcontroller, an arithmetic logic unit (“ALU”), and most notably, a central processing unit (“CPU”). A CPU, also called a central processor or main processor, is the electronic circuitry within a computer that carries out the instructions of a computer program by performing the basic arithmetic, logic, controlling, and input/output (“I/O”) operations specified by the instructions. Processing units are common in tablets, telephones, handheld devices, laptops, user displays, smart devices (TV, speaker, watch, etc.), and other computing devices.

A user interface is how the user interacts with a machine. The user interface can be a digital interface, a command-line interface, a graphical user interface (“GUI”), oral interface, virtual reality interface, or any other way a user can interact with a machine (user-machine interface). For example, the user interface (“UI”) can include a combination of digital and analog input and/or output devices or any other type of UI input/output device required to achieve a desired level of control and monitoring for a device. Examples of input and/or output devices include computer mice, keyboards, touchscreens, knobs, dials, switches, buttons, speakers, microphones, LIDAR, RADAR, etc. Input(s) received from the UI can then be sent to a microcontroller to control operational aspects of a device. The user interface module can include a display, which can act as an input and/or output device. More particularly, the display can be a liquid crystal display (“LCD”), a light-emitting diode (“LED”) display, an organic LED (“OLED”) display, an electroluminescent display (“ELD”), a surface-conduction electron emitter display (“SED”), a field-emission display (“FED”), a thin-film transistor (“TFT”) LCD, a bistable cholesteric reflective display (i.e., e-paper), etc. The user interface also can be configured with a microcontroller to display conditions or data associated with the main device in real-time or substantially real-time.

In some embodiments, the computer system 1100 could include one or more communications ports such as Ethernet, serial advanced technology attachment (“SATA”), universal serial bus (“USB”), or integrated drive electronics (“IDE”), for transferring, receiving, or storing data.

The disk drive unit may include a tangible computer-readable storage medium on which is stored one or more sets of instructions (e.g., software) embodying any one or more of the methods or functions described herein, including those methods illustrated above. The instructions may also reside, completely or at least partially, within the main memory, the static memory, and/or within the processor during execution thereof by the computer system. The main memory and the processor also may constitute tangible computer-readable storage media.

In communications and computing, a computer readable medium is a medium capable of storing data in a format readable by a mechanical device. The term “non-transitory” is used herein to refer to computer readable media (“CRM”) that store data for short periods or in the presence of power such as a memory device.

One or more embodiments described herein can be implemented using programmatic modules, engines, or components. A programmatic module, engine, or component can include a program, a sub-routine, a portion of a program, or a software component or a hardware component capable of performing one or more stated tasks or functions. A module or component can exist on a hardware component independently of other modules or components. Alternatively, a module or component can be a shared element or process of other modules, programs, or machines.

The memory includes, in some embodiments, a program storage area and/or data storage area. The memory can comprise read-only memory (“ROM”, an example of non-volatile memory, meaning it does not lose data when it is not connected to a power source) or random access memory (“RAM”, an example of volatile memory, meaning it will lose its data when not connected to a power source). Examples of volatile memory include static RAM (“SRAM”), dynamic RAM (“DRAM”), synchronous DRAM (“SDRAM”), etc. Examples of non-volatile memory include electrically erasable programmable read only memory (“EEPROM”), flash memory, hard disks, SD cards, etc. In some embodiments, the processing unit, such as a processor, a microprocessor, or a microcontroller, is connected to the memory and executes software instructions that are capable of being stored in a RAM of the memory (e.g., during execution), a ROM of the memory (e.g., on a generally permanent basis), or another non-transitory computer readable medium such as another memory or a disc.

Generally, the non-transitory computer readable medium operates under control of an operating system stored in the memory. The non-transitory computer readable medium implements a compiler which allows a software application written in a programming language such as COBOL, C++, FORTRAN, or any other known programming language to be translated into code readable by the central processing unit. After completion, the central processing unit accesses and manipulates data stored in the memory of the non-transitory computer readable medium using the relationships and logic dictated by the software application and generated using the compiler.

In at least some embodiments, the software application and the compiler are tangibly embodied in the computer-readable medium. When the instructions are read and executed by the non-transitory computer readable medium, the non-transitory computer readable medium performs the steps necessary to implement and/or use the present invention. A software application, operating instructions, and/or firmware (semi-permanent software programmed into read-only memory) may also be tangibly embodied in the memory and/or data communication devices, thereby making the software application a product or article of manufacture according to the present invention.

Dedicated hardware implementations including, but not limited to, application specific integrated circuits, programmable logic arrays and other hardware devices can likewise be constructed to implement the methods described herein. Applications that may include the apparatus and systems of various embodiments broadly include a variety of electronic and computer systems. Some embodiments implement functions in two or more specific interconnected hardware modules or devices with related control and data signals communicated between and through the modules, or as portions of an application-specific integrated circuit. Thus, the example system is applicable to software, firmware, and hardware implementations.

In accordance with various embodiments of the subject disclosure, the methods described herein are intended for operation as software programs running on a computer processor. Furthermore, software implementations can include, but not limited to, distributed processing or component/object distributed processing, parallel processing, or virtual machine processing can also be constructed to implement the methods described herein.

While the tangible computer-readable storage medium is in an exemplary embodiment to be a single medium, the term “tangible computer-readable storage medium” should be taken to include a single medium or multiple media (e.g., a centralized or distributed database, and/or associated caches and servers) that store the one or more sets of instructions. The term “tangible computer-readable storage medium” shall also be taken to include any non-transitory medium that is capable of storing or encoding a set of instructions for execution by the machine and that cause the machine to perform any one or more of the methods of the subject disclosure.

As has been included in the disclosure, many of the connections, such as those shown and/or described with respect to the connections between the servers and any of the collection devices, sensors, satellites, and the like, can be wired and/or wireless. It is further envisioned that the system can utilize cloud computing.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service.

A cloud computing environment is service oriented with a focus on statelessness, low coupling, modularity, and semantic interoperability. At the heart of cloud computing is an infrastructure comprising a network of interconnected nodes. The cloud computing can include use of a Private cloud (the cloud infrastructure is operated solely for an organization, and it may be managed by the organization or a third party and may exist on-premises or off-premises), Community cloud (the cloud infrastructure is shared by several organizations and supports a specific community that has shared concerns (e.g., mission, security requirements, policy, and compliance considerations), and it may be managed by the organizations or a third party and may exist on-premises or off-premises), Public cloud (the cloud infrastructure is made available to the general public or a large industry group and is owned by an organization selling cloud services), or a Hybrid cloud (the cloud infrastructure is a composition of two or more clouds (private, community, or public) that remain unique entities but are bound together by standardized or proprietary technology that enables data and application portability (e.g., cloud bursting for load balancing between clouds)).

In other embodiments of wireless connectivity, on or more networks are used. In some embodiments, the network is, by way of example only, a wide area network (“WAN”) such as a TCP/IP based network or a cellular network, a local area network (“LAN”), a neighborhood area network (“NAN”), a home area network (“HAN”), or a personal area network (“PAN”) employing any of a variety of communication protocols, such as Wi-Fi, Bluetooth, ZigBee, near field communication (“NFC”), etc., although other types of networks are possible and are contemplated herein. The network typically allows communication between the communications module and the central location during moments of low-quality connections. Communications through the network can be protected using one or more encryption techniques, such as those techniques provided by the Advanced Encryption Standard (AES), which superseded the Data Encryption Standard (DES), the IEEE 802.1 standard for port-based network security, pre-shared key, Extensible Authentication Protocol (“EAP”), Wired Equivalent Privacy (“WEP”), Temporal Key Integrity Protocol (“TKIP”), Wi-Fi Protected Access (“WPA”), and the like.

When wired connectivity is utilized, the system may utilize Ethernet. Ethernet is a family of computer networking technologies commonly used in local area networks (“LAN”), metropolitan area networks (“MAN”) and wide area networks (“WAN”). Systems communicating over Ethernet divide a stream of data into shorter pieces called frames. Each frame contains source and destination addresses, and error-checking data so that damaged frames can be detected and discarded; most often, higher-layer protocols trigger retransmission of lost frames. As per the OSI model, Ethernet provides services up to and including the data link layer. Ethernet was first standardized under the Institute of Electrical and Electronics Engineers (“IEEE”) 802.3 working group/collection of IEEE standards produced by the working group defining the physical layer and data link layer's media access control (“MAC”) of wired Ethernet. Ethernet has since been refined to support higher bit rates, a greater number of nodes, and longer link distances, but retains much backward compatibility. Ethernet has industrial application and interworks well with Wi-Fi. The Internet Protocol (“IP”) is commonly carried over Ethernet and so it is considered one of the key technologies that make up the Internet.

The Internet Protocol (“IP”) is the principal communications protocol in the Internet protocol suite for relaying datagrams across network boundaries. Its routing function enables internetworking, and essentially establishes the Internet. IP has the task of delivering packets from the source host to the destination host solely based on the IP addresses in the packet headers. For this purpose, IP defines packet structures that encapsulate the data to be delivered. It also defines addressing methods that are used to label the datagram with source and destination information.

The Transmission Control Protocol (“TCP”) is one of the main protocols of the Internet protocol suite. It originated in the initial network implementation in which it complemented the IP. Therefore, the entire suite is commonly referred to as TCP/IP. TCP provides reliable, ordered, and error-checked delivery of a stream of octets (bytes) between applications running on hosts communicating via an IP network. Major internet applications such as the World Wide Web, email, remote administration, and file transfer rely on TCP, which is part of the Transport Layer of the TCP/IP suite.

Transport Layer Security, and its predecessor Secure Sockets Layer (“SSL/TLS”), often runs on top of TCP. SSL/TLS are cryptographic protocols designed to provide communications security over a computer network. Several versions of the protocols find widespread use in applications such as web browsing, email, instant messaging, and voice over IP (“VoIP”). Websites can use TLS to secure all communications between their servers and web browsers.

As noted, and in addition to that previously included the term “tangible computer-readable storage medium” can accordingly be taken to include, but not be limited to: solid-state memories such as a memory card or other package that houses one or more read-only (non-volatile) memories, random access memories, or other re-writable (volatile) memories, a magneto-optical or optical medium such as a disk or tape, or other tangible media which can be used to store information. Accordingly, the disclosure is considered to include any one or more of a tangible computer-readable storage medium, as listed herein and including art-recognized equivalents and successor media, in which the software implementations herein are stored.

The terms “first,” “second,” “third,” and so forth, as used in the claims, unless otherwise clear by context, is for clarity only and does not otherwise indicate or imply any order in time. For instance, “a first-tier determination,” “a second-tier determination,” and “a third-tier determination,” does not indicate or imply that the first-tier determination is to be made before the second-tier determination, or vice versa, etc.

Moreover, it will be noted that the disclosed subject matter can be practiced with other computer system configurations, comprising single-processor or multiprocessor computer systems, mini-computing devices, mainframe computers, as well as personal computers, handheld computing devices (e.g., PDA, phone, smartphone, watch, tablet computers, netbook computers, etc.), microprocessor-based or programmable consumer or industrial electronics, and the like. The illustrated aspects can also be practiced in distributed computing environments where tasks are performed by remote processing devices that are linked through a communications network; however, some if not all aspects of the subject disclosure can be practiced on stand-alone computers. In a distributed computing environment, program modules can be located in both local and remote memory storage devices.

In one or more embodiments, information regarding vehicle movement history, user preferences, and so forth can be accessed. This information can be obtained by various methods including user input, detecting types of communications, analysis of content streams, sampling, and so forth. The generating, obtaining and/or monitoring of this information can be responsive to an authorization provided by the user. In one or more embodiments, an analysis of data can be subject to authorization from user(s) associated with the data, such as an opt-in, an opt-out, acknowledgement requirements, notifications, selective authorization based on types of data, and so forth.

As used in some contexts in this application, in some embodiments, the terms “component,” “system” and the like are intended to refer to, or comprise, a computer-related entity or an entity related to an operational apparatus with one or more specific functionalities, wherein the entity can be either hardware, a combination of hardware and software, software, or software in execution. As an example, a component may be, but is not limited to being, a process running on a processor, a processor, an object, an executable, a thread of execution, computer-executable instructions, a program, and/or a computer. By way of illustration and not limitation, both an application running on a server and the server can be a component. One or more components may reside within a process and/or thread of execution and a component may be localized on one computer and/or distributed between two or more computers. In addition, these components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor, wherein the processor can be internal or external to the apparatus and executes at least a part of the software or firmware application. As yet another example, a component can be an apparatus that provides specific functionality through electronic components without mechanical parts, the electronic components can comprise a processor therein to execute software or firmware that confers at least in part the functionality of the electronic components. While various components have been illustrated as separate components, it will be appreciated that multiple components can be implemented as a single component, or a single component can be implemented as multiple components, without departing from example embodiments.

Further, the various embodiments can be implemented as a method, apparatus or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device or computer-readable storage/communications media. For example, computer readable storage media can include, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick, key drive). Of course, those skilled in the art will recognize many modifications can be made to this configuration without departing from the scope or spirit of the various embodiments.

In addition, the words “example” and “exemplary” are used herein to mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. As used in this application, the term “or” is intended to mean an inclusive “or” rather than an exclusive “or”. That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

As used herein, terms such as “data storage,” “database,” and substantially any other information storage component relevant to operation and functionality of a component, refer to “memory components,” or entities embodied in a “memory” or components comprising the memory. It will be appreciated that the memory components or computer-readable storage media, described herein can be either volatile memory or nonvolatile memory or can include both volatile and nonvolatile memory.

The database is a structured set of data typically held in a computer. The database, as well as data and information contained therein, need not reside in a single physical or electronic location. For example, the database may reside, at least in part, on a local storage device, in an external hard drive, on a database server connected to a network, on a cloud-based storage system, in a distributed ledger (such as those commonly used with blockchain technology), or the like.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

In addition, a flow diagram may include a “start” and/or “continue” indication. The “start” and “continue” indications reflect that the steps presented can optionally be incorporated in or otherwise used in conjunction with other routines. In this context, “start” can indicate, for example, the beginning of the first-tier step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first-tier item to a second-tier item may be modified by one or more intervening items by modifying the form, nature, or format of information in a signal, while one or more elements of the information in the signal are nevertheless conveyed in a manner than can be recognized by the second-tier item. In a further example of indirect coupling, an action in a first-tier item can cause a reaction on the second-tier item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments may be utilized and derived therefrom, such that structural and logical substitutions and changes may be made without departing from the scope of this disclosure. Figures are also merely representational and may not be drawn to scale. Certain proportions thereof may be exaggerated, while others may be minimized. Accordingly, the specification and drawings are to be regarded in an illustrative rather than a restrictive sense.

From the foregoing, it can be seen that the invention accomplishes at least all of the stated objectives.

1. A data-driven scaling method to estimate one or more hydrological and water quality variables at a watershed outlet based on model-simulated hydrological and water quality variables over multiple granular cells within the watershed, the method comprising:
a. collecting observation data of one or more hydrological and water quality variables at a watershed outlet over a first period of time;
b. conducting process-based model simulation over multiple granular cells within the watershed outlet over the first period of time; and
c. building statistical or machine learning models with observation data and model simulated data to estimate one or more hydrological and water quality variables at a watershed outlet.

2. The method of claim 1, wherein the hydrological and water quality variables at a watershed outlet comprise discharge rate, stage, sediment, nutrient, and/or pollutant loads or concentrations.

3. The method of claim 1, wherein the hydrological and water quality variables over multiple granular cells within the watershed include surface and surface runoff, sediment, nutrient, and/or pollutant fluxes.

4. The method of claim 1, wherein the observation data at a watershed outlet can be collected from either existing observation stations or newly deployed sensors.

5. The method of claim 1, wherein the process-based model comprises any types of models that can fully or partially simulate the water, sediment, nutrient and pollutant fluxes over a land parcel with physical knowledge.

6. The method of claim 1, wherein the granular cells can be regular grids, irregular subfield or fields, sub-watersheds, and other defined hydrologic response units that are smaller than a studied watershed.

7. An irrigation triggering method based on the concept of water supply-demand dynamics (SDD), which concurrently considers the impact of both soil water condition and atmospheric aridity on crop water conditions, the method comprising:
a) obtaining data of soil water condition and atmospheric aridity;
b) determining different irrigation triggering thresholds for soil water conditions under different atmospheric aridity conditions;
c) triggering an irrigation event when soil water condition data falls below the irrigation triggering threshold determined in step b) under an atmospheric aridity condition; and
d) determining an irrigation amount based on a targeted soil water condition and limits from irrigation water supply.

8. The method of claim 7, wherein soil water condition and atmospheric aridity are directly measured using sensors, remote sensing, or obtained using statistical models or model simulation.

9. The method of claim 7, wherein soil water condition and atmospheric aridity are forecasted data from statistical models or model simulations, which enables generating a forecasted irrigation scheduling.

10. The method of claim 7, wherein the irrigation triggering thresholds for soil water conditions under different atmospheric aridity conditions are different for different locations or cropping systems.

11. A method for inferring historical or real-time irrigation time and amount with remotely sensed satellite-based evapotranspiration (ET) observations at a field or subfield scale high resolution, comprising:
a) collecting input data to a process-based model that can simulate hydrological processes over cropland and remotely sensed ET data;
b) running the process-based model with collected input data in step a) and prescribed irrigation information;
c) determining irrigation time and amount by ensuring model simulated ET to match the remotely sensed ET, using a model-data fusion technique;
wherein the irrigation time and amount can be determined either concurrently or sequentially.

12. The method of claim 11, wherein the model-data fusion technique comprises one or more of sequential data assimilation algorithms (such as Kalman Filter, Extended Kalman Filter, Ensemble Kalman Filter, different variants of Ensemble Square Root Filters and Particle Filters), and continuous data assimilation algorithms (such as three-dimensional or four-dimensional variational data assimilation algorithms, and different types of global optimization algorithms).

13. The method of claim 11, wherein the remotely sensed ET data is derived from different platforms including satellite, airborne, or unmanned aerial vehicles.

14. The method of claim 11, wherein the irrigation time and amount are determined by comparing the model simulated ET and observed ET.

15. A method of predicting crop type classification for an ongoing growing season comprising:
a. optimizing a first machine learning or statistical model that predicts a planted crop type from a historical record of planted crop types;
b. optimizing a second machine learning or statistical model that predicts the planted crop type from remotely sensed data of the current growing season; and
c. deriving a final planted crop type prediction by combining the models, predictions, or predicted likelihoods, of the first and second models.

16. The method of claim 15, wherein the remotely sensed data can be satellite data, satellite-derived indices, airborne remote sensing data, UAV-collected data, data collected by ground vehicles, and/or synthetic data generated from any combination of the aforementioned sources.

17. The method of claim 15, wherein the combination of predicted likelihoods is achieved by training on or more instances of the first and/or second model and taking a vote of model predictions.

18. The method of claim 15, wherein the combination of predicted likelihoods is determined by summing likelihoods of class labels in each model in a log space, with or without weights.

19. The method of claim 15, wherein after generating the final predictions, a number of fields within a geographic or administrative region with a certain crop type label is counted hence generating an aggregated prediction of the total number of fields of a certain crop type within the geographic or administrative region.

20. The method of claim 15, wherein after generating the final predictions, areas of all fields within a geographic or administrative region with a certain crop type label are summed up, hence generating an aggregated prediction of the total planted acreage of a certain crop type within the geographic or administrative region.
